(19) United States
(12) Patent Application Publication
(10) Pub. No.: US 2026/0228627 A1
(43) Pub. Date: Aug. 6, 2026

(54) TRAINING DESIGN GENERATIVE MODELS USING SIMULATION

(71) Applicant: AUTODESK, INC., San Francisco, CA (US)

(72) Inventors: Hyunmin CHEONG, Toronto (CA); Mohammadmehdi ATAEI, Toronto (CA); Amir Hosein KHAS AHMADI, Toronto (CA); Pradeep Kumar JAYARAMAN, Toronto (CA)

(21) Appl. No.: 19/450,598

(22) Filed: Jan. 15, 2026

Related U.S. Application Data
(60) Provisional application No. 63/753,364, filed on Feb. 3, 2025.

(51) Int. Cl. G06N 20/00

(52) U.S. Cl. CPC G06N 20/00

(57) ABSTRACT

One embodiment sets forth a technique for training a generative model to generate one or more designs that includes receiving first requirement data; performing, using a simulator and a first trained machine learning model, one or more operations to generate one or more requirement-satisfying designs based on the first requirement data, where the first trained machine learning model is trained to generate one or more first designs based on the first requirement data; performing, based on the one or more requirement-satisfying designs and the first requirement data, one or more training operations to retrain the first trained machine learning model to generate a second trained machine learning model; and generating, based on one or more first requirements and using the second trained machine learning model, one or more first predicted designs.

### CROSS-REFERENCE TO RELATED APPLICATIONS

This application claims priority benefit of the U.S. Provisional patent application titled, “TECHNIQUES FOR ALIGNING GENERATIVE AI MODELS WITH SIMULATION FEEDBACK,” filed on Feb. 3, 2025, and having Ser. No. 63/753,364. The subject matter of this related application is hereby incorporated herein by reference.

### BACKGROUND

### Technical Field

Embodiments of the present disclosure relate generally to computer-aided design, model-based systems engineering, artificial intelligence, and machine learning, and, more specifically, to techniques for aligning design generative models using simulation.

### Description of the Related Art

Design generation refers to the generation of digital design candidates using computational models that map input conditions, such as requirements and/or the like, to structured representations of physical or engineered systems. In recent years, design generative models, such as neural networks trained on collections of geometry, configuration parameters, or performance labeled data, have been used to generate designs that satisfy user specified conditions, requirements, or target performance values. For example, a design generative model can generate aerodynamic shapes conditioned on airflow parameters, structural components conditioned on load or stiffness specifications, or thermal system layouts conditioned on temperature or heat flow constraints. In product development and engineering contexts, design generative models can enable rapid exploration of large design spaces and can generate diverse candidate designs.

Conventional approaches for design generation using design generative models often rely on static datasets collected from existing product designs, historical engineering models, or curated design repositories. The datasets include geometric models, computer aided design (CAD) assemblies, architectural layouts, circuit schematics, or other structured representations that capture prior design solutions. In conventional approaches, requirement values or high level specifications are used to condition a design generative model that has been trained or fine tuned solely on the historical or example based design data. The design generative model learns correlations, structural patterns, and stylistic relationships present within the examples included in the dataset and can generate new designs consistent with the patterns observed in the dataset.

At least one technical drawback of the foregoing approaches is that, under the foregoing approaches, design generative models trained using static datasets tend to exhibit limited performance when required to generalize beyond the data on which the design generative models were trained. Because such static datasets are typically constructed from historical design files, curated CAD repositories, engineering drawings, or expert generated design examples, the resulting data distribution cannot fully reflect the full range of feasible or physically valid designs. As a result, when a design generative model is trained solely on such limited or low quality static datasets, which could omit physically extreme cases, boundary-condition violations, manufacturability constraints, or rare but valid structural configurations, the design generative model could generate designs that fail to satisfy real world physical, mechanical, thermal, or aerodynamic performance requirements when evaluated under actual simulation or operational conditions.

Another technical drawback of the above approaches is that, because the static datasets generally lack explicit physics based feedback, the design generative model receives no corrective signal indicating whether a generated design meets or fails to meet underlying performance requirements. As a result, a design generative model trained on such limited and low fidelity data could learn correlations that hold only within the dataset but fail to capture the underlying physical principles governing real-world behavior, causing the design generative model to generate designs that appear geometrically plausible while exhibiting physically invalid or noncompliant mechanical, thermal, or aerodynamic characteristics during simulation or evaluation. As the foregoing illustrates, what is needed in the art are more effective techniques for training design generative models.

### SUMMARY

One embodiment sets forth a computer-implemented method for training a generative model to generate one or more designs. The method includes receiving first requirement data. The method also includes performing, using a simulator and a first trained machine learning model, one or more operations to generate one or more requirement-satisfying designs based on the first requirement data, where the first trained machine learning model is trained to generate one or more first designs based on the first requirement data. The method further includes performing, based on the one or more requirement-satisfying designs and the first requirement data, one or more training operations to retrain the first trained machine learning model to generate a second trained machine learning model. In addition, the method includes generating, based on one or more first requirements and using the second trained machine learning model, one or more first predicted designs

In some embodiments, a computer-implemented method for training a generative model to generate one or more designs includes receiving requirement data. The method also includes performing, using a simulator and a first trained machine learning model, one or more operations to generate one or more preferred designs and one or more rejected designs, where the first trained machine learning model is trained to generate one or more first designs based on the requirement data. The method further includes performing, based on the requirement data, the one or more preferred designs, and the one or more rejected designs, one or more training operations to retrain the first trained machine learning model to generate a second trained machine learning model. In addition, the method includes generating, based on one or more first requirements and using the second trained machine learning model, one or more first predicted designs.

In some embodiments, a computer-implemented method for training a generative model to generate one or more designs includes receiving requirement data. The method also includes performing, based on the requirement data, one or more operations to generate one or more design trajectories using a first trained machine learning model, where the first trained machine learning model is trained to generate one or more first designs. The method further includes performing, based on the requirement data and the one or more design trajectories, one or more training operations to retrain the first trained machine learning model to generate a second trained machine learning model. In addition, the method includes generating, based on one or more first requirements and using the second trained machine learning model, one or more first predicted designs.

Other embodiments of the present disclosure include, without limitation, one or more computer-readable media including instructions for performing one or more aspects of the disclosed techniques as well as a computing device for performing one or more aspects of the disclosed techniques.

At least one technical advantage of the disclosed techniques relative to the prior art is that the disclosed techniques use simulation to provide accurate physics based supervisory signals that directly reflect real world performance and thereby overcome limitations associated with historical datasets that are static in nature. Rather than relying solely on curated CAD files, engineering drawings, or manually constructed examples, the disclosed techniques generate training data, preference feedback, or reward signals through a design simulator that evaluates each generated design under relevant physical, mechanical, thermal, aerodynamic, or electrical conditions. Another technical advantage of the disclosed techniques is that the disclosed techniques enable continuous refinement of a design generative model using simulation-derived bound values, preferences, or rewards without a requirement for human labels, expert review, or manual correction steps. Accordingly, the disclosed techniques improve technical performance, accuracy, and generalization capability of design generative models by aligning design generative models with simulator feedback during training.

These technical advantages provide one or more technological improvements over prior art approaches.

### BRIEF DESCRIPTION OF THE DRAWINGS

So that the manner in which the above recited features of the various embodiments can be understood in detail, a more particular description of the inventive concepts, briefly summarized above, can be had by reference to various embodiments, some of which are illustrated in the appended drawings. It is to be noted, however, that the appended drawings illustrate only typical embodiments of the inventive concepts and are therefore not to be considered limiting of scope in any way, and that there are other equally effective embodiments.

FIG. 1 is a block diagram of a computer system configured to implement one or more aspects of various embodiments;

FIG. 2A is a more detailed illustration of the machine learning server of FIG. 1, according to various embodiments;

FIG. 2B is a more detailed illustration of the computing device of FIG. 1, according to various embodiments;

FIG. 3A is a more detailed illustration of the design simulator of FIG. 1 generating the design data of FIG. 1, according to various embodiments;

FIG. 3B is a more detailed illustration of the model trainer of FIG. 1 training the design generative model of FIG. 1 based on the design data of FIG. 1, according to various embodiments;

FIG. 4A is a more detailed illustration of the second requirement data generator of FIG. 1, according to various embodiments;

FIG. 4B is a more detailed illustration of the model trainer of FIG. 1 training the design generative model of FIG. 1 based on first requirement data and second requirement data, according to various embodiments;

FIG. 5A is a more detailed illustration of the preferred and rejected designs generator of FIG. 1, according to various embodiments;

FIG. 5B is a more detailed illustration of the model trainer of FIG. 1 training the design generative model of FIG. 1 based on preferred designs and rejected designs, according to various embodiments;

FIG. 6A is a more detailed illustration of the design trajectory generator of FIG. 1, according to various embodiments;

FIG. 6B is a more detailed illustration of the model trainer of FIG. 1 training the design generative model of FIG. 1 based on the design trajectory data of FIG. 1, according to various embodiments;

FIG. 7 is a more detailed illustration of the design generation application of FIG. 1, according to various embodiments;

FIG. 8 is a flow diagram of method steps for generating requirement-satisfying designs, according to various embodiments;

FIG. 9 is a flow diagram of method steps for training design generative model based on requirement-satisfying designs, according to various embodiments;

FIG. 10 is a flow diagram of method steps for generating second requirement data, according to various embodiments;

FIG. 11 is a flow diagram of method steps for training design generative model based on first requirement data and second requirement data, according to various embodiments;

FIG. 12 is a flow diagram of method steps for generating preferred designs and rejected designs, according to various embodiments;

FIG. 13 is a flow diagram of method steps for training design generative model based on preferred designs and rejected designs, according to various embodiments;

FIG. 14 is a flow diagram of method steps for training design generative model based on design trajectory data, according to various embodiments; and

FIG. 15 is a flow diagram of method steps for generating a predicted design, according to various embodiments.

### DETAILED DESCRIPTION

In the following description, numerous specific details are set forth to provide a more thorough understanding of the various embodiments. However, it will be apparent to one skilled in the art that the concepts can be practiced without one or more of these specific details.

### General Overview

Embodiments of the present disclosure provide techniques for training a design generative model using simulation. The design generative model is a machine learning model that is trained to process one or more first requirements and generate one or more first designs. The design generative model includes a first encoder, a second encoder, and a decoder. The first encoder and the second encoder are each another machine learning model that processes the first requirements and generates a requirement embedding. The decoder is yet another machine learning model that processes the requirement embedding and generates the first designs. In some embodiments, a model trainer trains the design generative model based on one or more requirement satisfying-designs generated by a design simulator. During the training, the design generative model uses the first encoder and the decoder to process the first requirements included in requirement data and generate the first designs. The design simulator simulates the first designs to determine the requirement satisfying-designs based on the first requirements. A loss calculator calculates a first loss based on the first designs and the requirement satisfying-designs. The model trainer uses the first loss to update one or more parameters of the decoder iteratively until one or more stopping criteria are met.

In some embodiments, a second requirement data generator uses the design simulator and the design generative model to process one or more second requirements and the first requirements included in first requirement data and generate second requirement data. During second requirement data generation, the design generative model uses the first encoder and the decoder to process the first requirements and generate one or more second designs. A second requirement bound value generator uses the design simulator to process the second designs and the second requirements and generate second requirement bound values, which are stored in the second requirement data along with the second requirements. The model trainer then trains the design generative model based on the first requirement data, the second requirement data, and design data. During the training, the first encoder processes the first requirement data and generates a first embedding. The second encoder processes the second requirement data and generates a second embedding. The decoder processes at least one of the first embedding and the second embedding to generate one or more first predicted designs. The loss calculator calculates a second loss based on the first predicted designs and the design data. The model trainer updates one or more parameters of the second encoder and the decoder based on the second loss until one or more stopping criteria are met.

In some embodiments, a preferred and rejected designs generator uses the design generative model and the design simulator to generate one or more preferred designs and one or more rejected designs based on the first requirement data and the second requirement data. During the design generation, the design generative model uses the decoder and at least one of the first encoder or the second encoder to process the first requirements and the second requirements and generate one or more third designs. The design simulator simulates the third designs and determines one or more design performance values based on the requirements. The preferred and rejected designs generator processes the third designs and the design performance values and generates the preferred designs and the rejected designs. The model trainer then trains the design generative model based on the first requirement data, the second requirement data, the preferred designs, and the rejected designs. During the training, at least one of the first encoder or the second encoder processes the first requirements and the second requirements and generates the requirement embedding. The decoder processes the requirement embedding and generates one or more second predicted designs. The loss calculator calculates a third loss based on the second predicted designs, the rejected designs, and the preferred designs. The model trainer updates parameters of the decoder based on the third loss iteratively until one or more stopping criteria are met.

In some embodiments, the model trainer trains the design generative model based on design trajectory data. A design trajectory generator uses the design generative model and the design simulator to process the first requirements and the second requirements and generate the design trajectory data. The design generative model uses at least one of the first encoder or the second encoder to process the first requirements and the second requirements and generate one or more fourth designs. A design reward generator uses the design simulator to simulate the fourth designs to generate one or more design rewards based on the first requirements and the second requirements. The design rewards along with the fourth designs are stored in the design trajectory data. During the training, the design generative model uses at least one of the first encoder or the second encoder and the decoder to process the first requirements and the second requirements and generate one or more third predicted designs. The loss calculator calculates a fourth loss based on the third predicted designs and one or more design trajectories included in the design trajectory data. The model trainer uses the fourth loss to update parameters of the decoder iteratively until one or more stopping criteria are met.

Once trained, the trained design generative model can be used by a design generation application to process one or more third requirements received from I/O devices and generate a fourth predicted design.

The design generative model training techniques of the present disclosure have numerous real-world applications. For example, the disclosed techniques can be used in product development and industrial design to train design generative models that generate candidate geometries, assemblies, and configurations aligned with physical performance criteria evaluated by simulators. In aerospace and automotive engineering, design generative models trained using simulation can generate aerodynamic surfaces, structural components, or thermal management systems that meet performance goals derived from computational fluid dynamics or finite element simulations. In robotics and mechatronics, the disclosed techniques can be used to train design generative models that generate mechanisms, linkages, or actuator layouts evaluated through multibody dynamics or control-system simulators. In electronics and materials engineering, the disclosed techniques can train design generative models to generate circuit layouts, heat-spreading structures, or composite material patterns that satisfy electromagnetic, thermal, or stress-distribution requirements. Additionally, the disclosed techniques can be applied in other fields, such as architecture, energy systems, and industrial automation, to generate design alternatives that are aligned with domain-specific simulation tools, thereby supporting simulation-driven exploration, optimization, and refinement of generated designs.

The above examples are not in any way intended to be limiting. As persons skilled in the art will appreciate, as a general matter, the virtual object generation techniques described herein can be implemented in any suitable application.

### System Overview

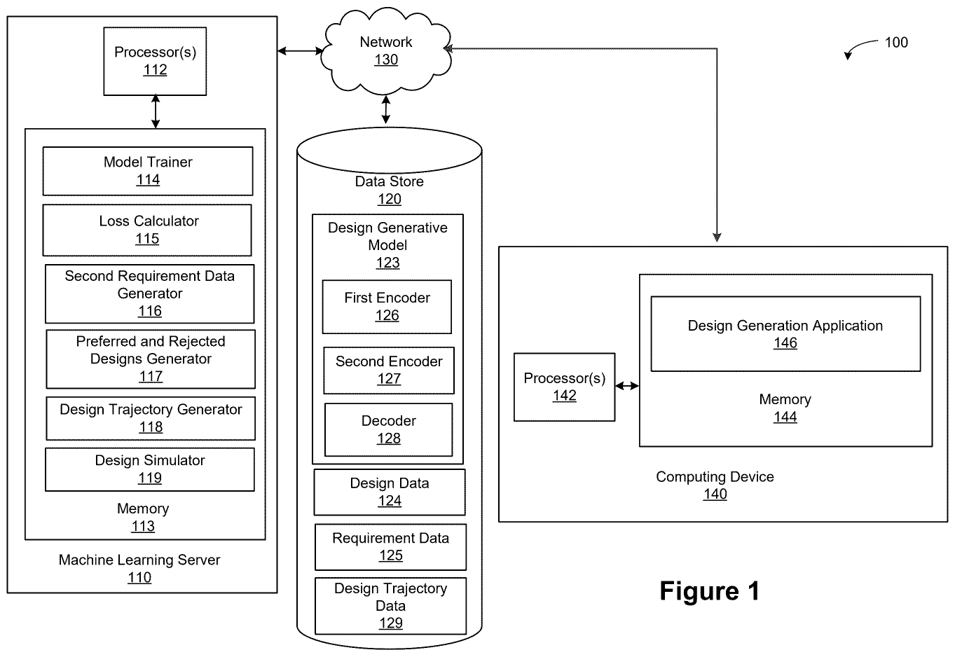

FIG. 1 illustrates a block diagram of a computer-based system 100 configured to implement one or more aspects of at least one embodiment. As shown, system 100 includes a machine learning server 110, a data store 120, and a computing device 140 in communication over a network 130. Network 130 can be a wide area network (WAN) such as the Internet, a local area network (LAN), a cellular network, and/or any other suitable network. Machine learning server 110 includes, without limitation, processor(s) 112 and a memory 113. Memory 113 includes, without limitation, a model trainer 114, a loss calculator 115, a second requirement data generator 116, a preferred and rejected designs generator 117, a design trajectory generator 118, and a design simulator 119. Data store 120 includes, without limitation, a design generative model 123, design data 124, requirement data 125, and design trajectory data 129. Design generative model 123 includes, without limitation, a first encoder 126, a second encoder 127, and a decoder 128. Computing device 140 includes, without limitation, processor(s) 142 and a memory 144. Memory 144 includes, without limitation, a design generation application 146.

Processor(s) 112 receive user input from input devices, such as a keyboard or a mouse. Processor(s) 112 may include one or more primary processors of machine learning server 110, which control and coordinate operations of other system components. In particular, processor(s) 112 can issue commands that control the operation of one or more graphics processing units (GPUs) (not shown) and/or other parallel processing circuitry (e.g., parallel processing units, deep learning accelerators, etc.) that incorporates circuitry that is optimized for graphics and video processing, including, for example, video output circuitry. The GPU(s) can deliver pixels to a display device that can be any conventional cathode ray tube, liquid crystal display, light-emitting diode display, and/or similar technologies.

Memory 113 of machine learning server 110 stores content, such as software applications and data, for use by processor(s) 112 and the GPU(s) and/or other processing units. Memory 113 can be any type of memory capable of storing data and software applications, such as a random-access memory (RAM), a read-only memory (ROM), an erasable programmable read-only memory (EPROM or Flash ROM), or any suitable combination of the foregoing. In some embodiments, a storage (not shown) can supplement or replace memory 113. The storage can include any number and type of external memories that are accessible to processor(s) 112 and/or the GPU. For example, and without limitation, the storage can include a Secure Digital Card, an external Flash memory, a portable compact disc read-only memory (CD-ROM), an optical storage device, a magnetic storage device, and/or any suitable combination of the foregoing.

Machine learning server 110 shown herein is for illustrative purposes only, and variations and modifications are possible without departing from the scope of the present disclosure. For example, the number of processors 112, the number of GPUs and/or other processing unit types, the number of memories 113, and/or the number of applications included in memory 113 can be modified as desired. Further, the connection topology between the various units in FIG. 1 can be modified as desired. In some embodiments, any combination of processor(s) 112, memory 113, and/or GPUs can be included in and/or replaced with any type of virtual computing system, distributed computing system, and/or cloud computing environment, such as a public, private, or hybrid cloud system.

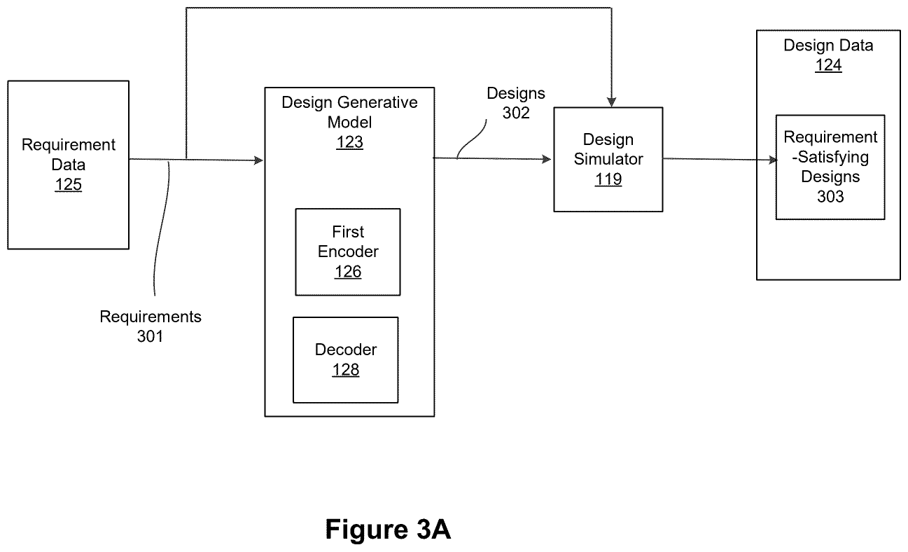

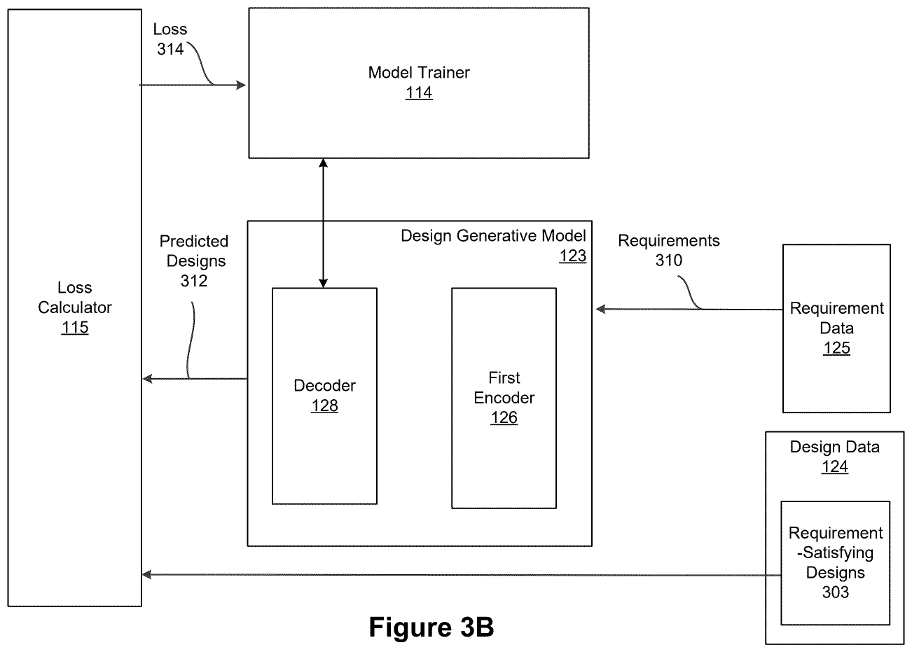

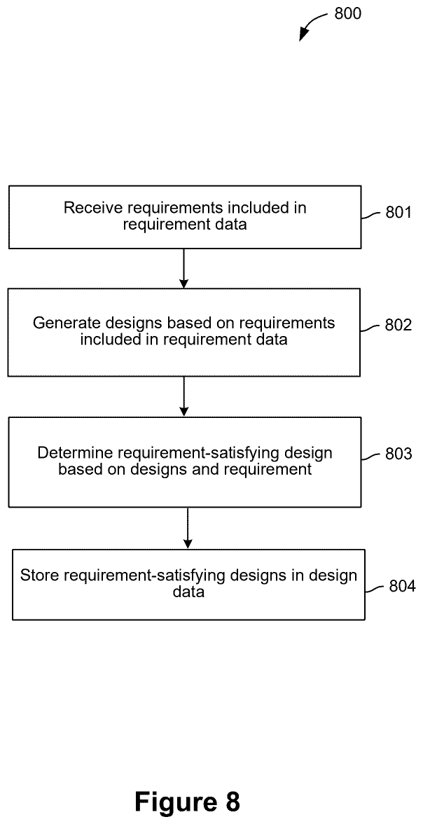

As shown, design simulator 119 executes on processor(s) 112 of machine learning server 110 and is stored in memory 113 of machine learning server 110. In some embodiments, design simulator 119 is an application that processes one or more designs and a requirement and determines a requirement-satisfying design. In some embodiments, design simulator 119 simulates one or more designs and determines one or more second requirement values for the designs based on one or more second requirements. Design simulator 119 is described in greater detail herein at least in conjunction with FIGS. 3A and 8.

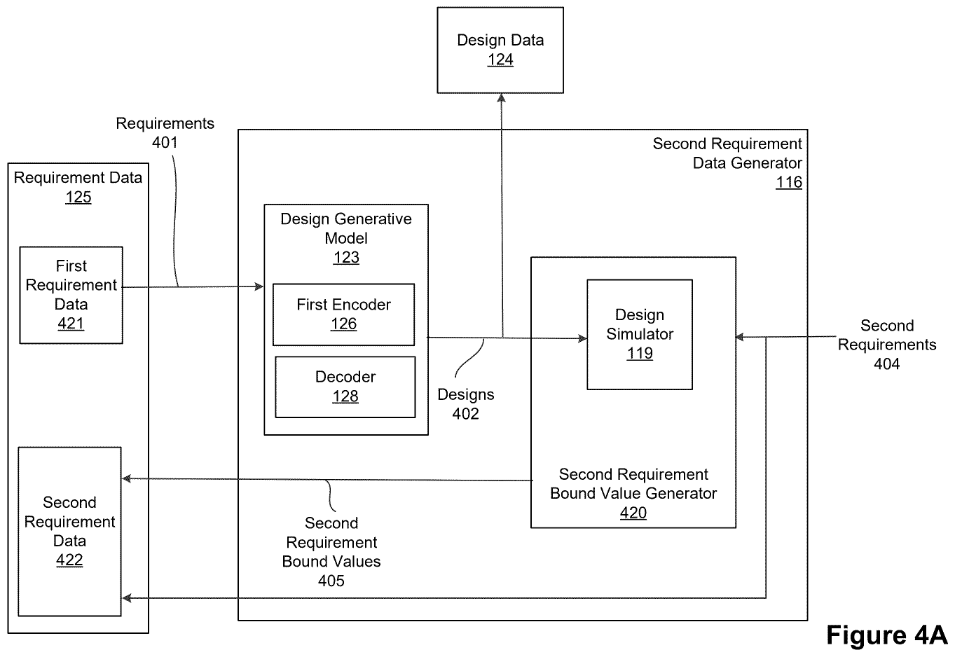

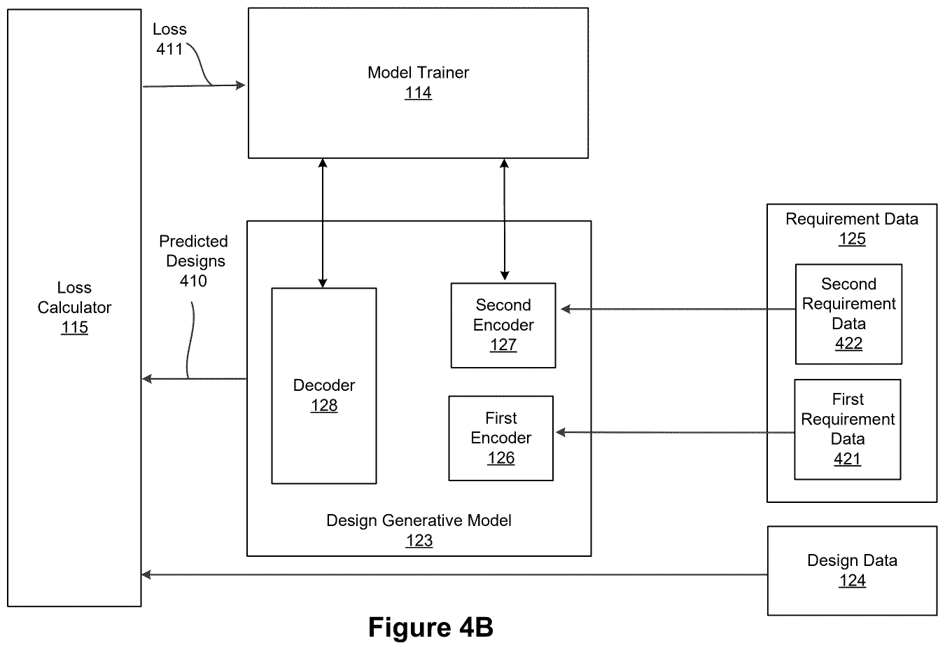

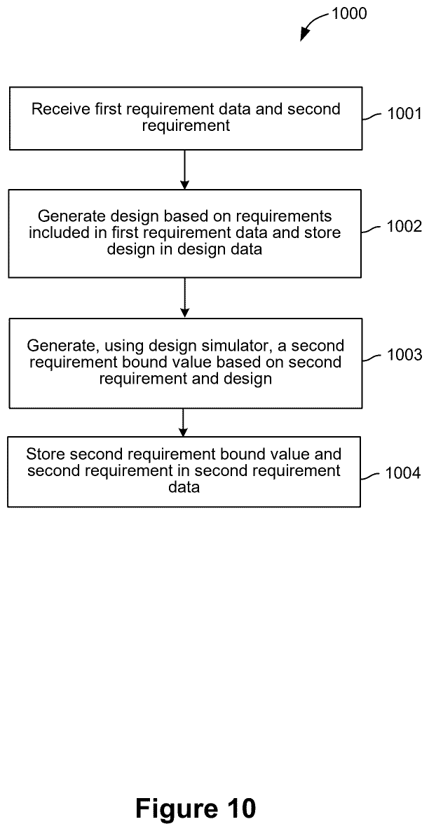

Second requirement data generator 116 executes on processor(s) 112 of machine learning server 110 and is stored in memory 113 of machine learning server 110. In some embodiments, second requirement data generator 116 is an application that processes one or more requirements and the second requirements and generates second requirement data. Second requirement data generator 116 is described in greater detail herein at least in conjunction with FIGS. 4A and 10.

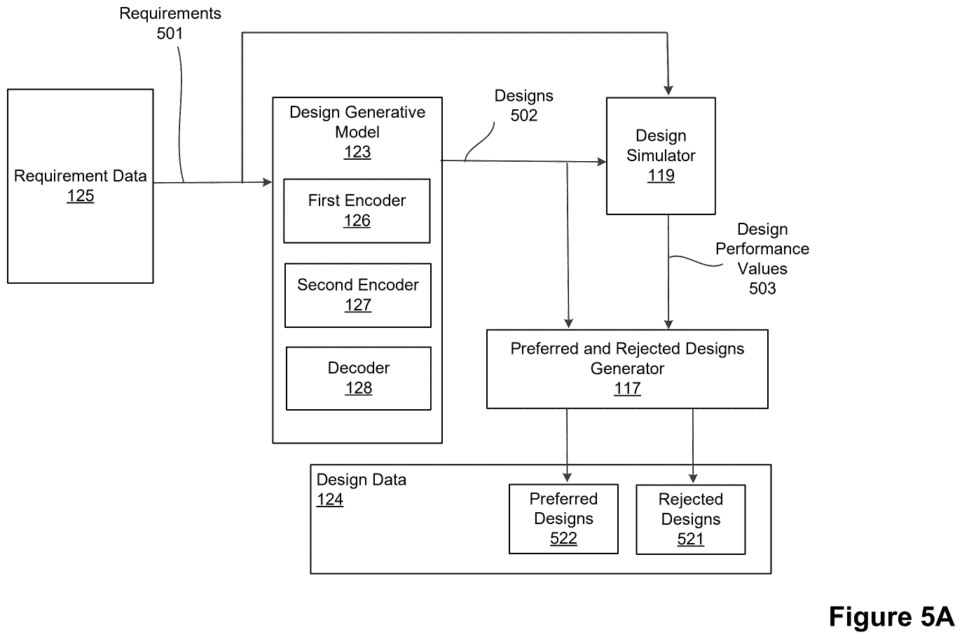

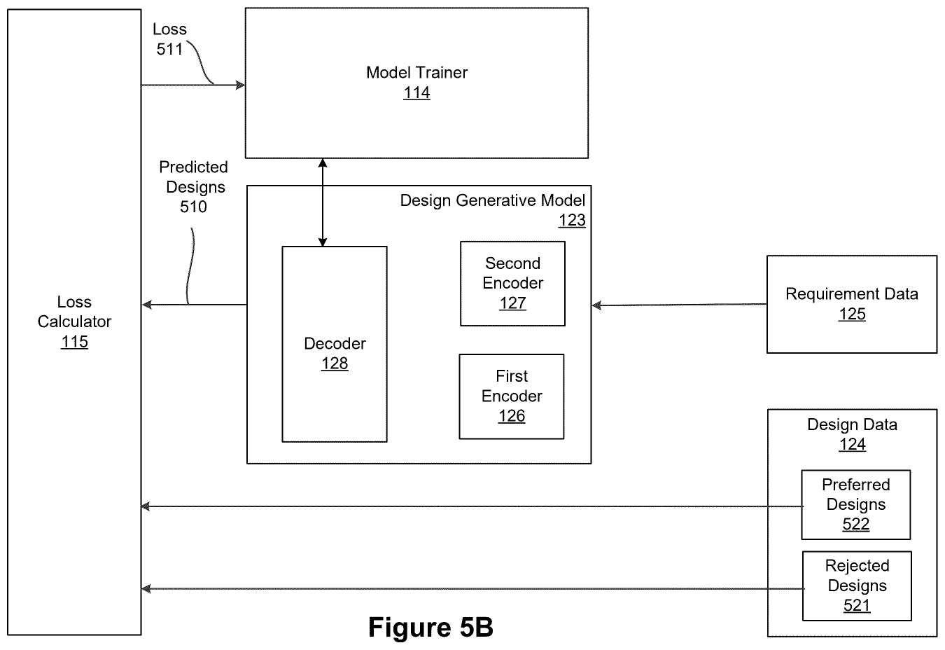

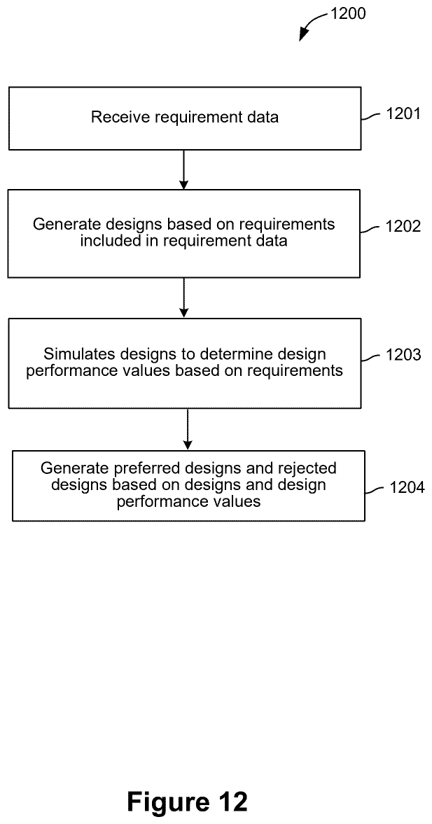

Preferred and rejected designs generator 117 executes on processor(s) 112 of machine learning server 110 and is stored in memory 113 of machine learning server 110. In some embodiments, preferred and rejected designs generator 117 is an application that processes the designs and the design performance values and generates preferred designs and rejected designs. Preferred and rejected designs generator 117 is described in greater detail herein at least in conjunction with FIGS. 5A and 12.

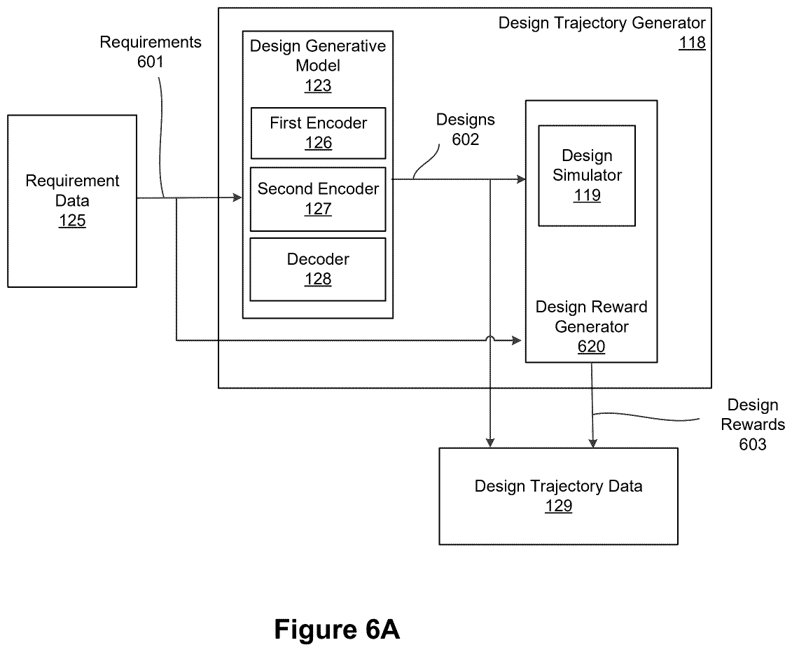

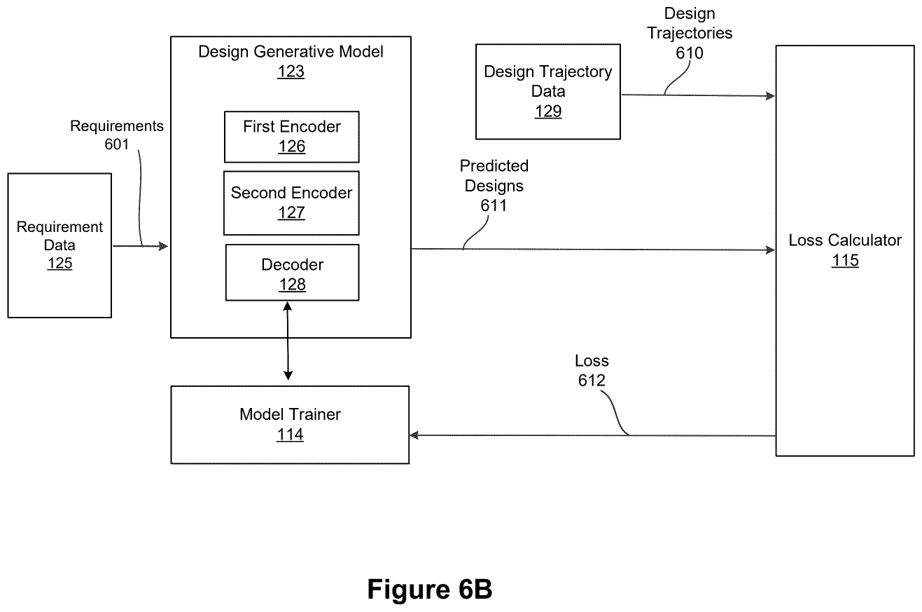

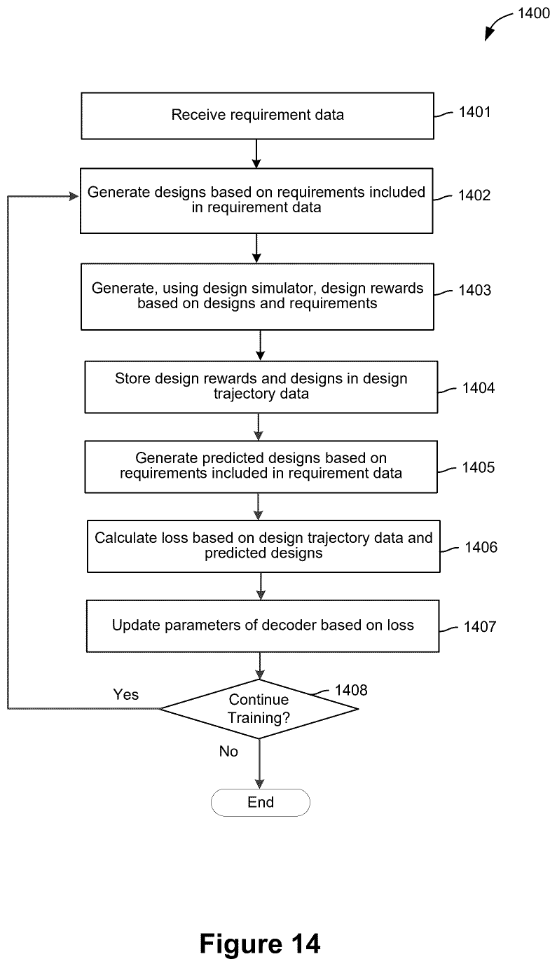

Design trajectory generator 118 executes on processor(s) 112 of machine learning server 110 and is stored in memory 113 of machine learning server 110. In some embodiments, design trajectory generator 118 is an application that uses design simulator 119 to process the requirements and generate design trajectory data 129. Design trajectory data 129 stored in data store 120 includes one or more designs and the corresponding design rewards. Design trajectory generator 118 is described in greater detail herein at least in conjunction with FIGS. 6A and 14.

Loss calculator 115 executes on processor(s) 112 of machine learning server 110 and is stored in memory 113 of machine learning server 110. In some embodiments, loss calculator 115 is an application that calculates a first loss based on the requirement-satisfying design and a predicted design. In some embodiments, loss calculator 115 calculates a second loss based on design data and the predicted design. In some embodiments, loss calculator 115 calculates a third loss based on the preferred designs, the rejected designs, and the predicted design. In some embodiments, loss calculator 115 calculates a fourth loss based on one or more design trajectories and one or more predicted designs.

Model trainer 114 is an application that executes on one or more processors 112 of machine learning server 110 and is stored in memory 113 of machine learning server 110. Although shown as distinct from loss calculator 115 for illustrative purposes, in some embodiments, functionality of loss calculator 115 and model trainer 114 can be combined into a single application or separated into any number of applications.

In some embodiments, model trainer 114 is configured to train and/or retrain one or more machine learning models, including design generative model 123. Design generative model 123 is a machine learning model, such as a neural network, which is trained to generate one or more predicted designs based on the requirements. Techniques for training design generative model 123 based on requirement data 125 and design data 124 are described in greater detail in conjunction with at least FIGS. 3B, 4B, 5B, 9, 11, and 13. Techniques for training design generative model 123 based on requirement data 125 and design trajectory data 129 are described in greater detail in conjunction with at least FIGS. 6B and 14. Requirement data 125 stored in data store 120 includes one or more requirements and corresponding requirement values that define the design objectives and constraints for design generation. For example, requirement data 125 can include aerodynamic efficiency targets, structural load limits, thermal dissipation thresholds, manufacturing cost budgets, material weight limits, regulatory compliance conditions, and/or similar data. In some embodiments, requirement data 125 includes first requirement data and second requirement data. Design data 124 stored in data store 120 includes one or more designs. For example, design data 124 can include geometric CAD meshes, parametric component configurations, mechanical assemblies, electrical layouts, structural topologies, three-dimensional (3D) surface representations, and/or similar data. In some embodiments, design data 124 includes requirement-satisfying designs, such as wing shapes that meet a specified lift-to-drag ratio, battery enclosures that meet thermal constraints, or bracket geometries that satisfy structural stiffness targets. In some embodiments, design data 124 includes preferred designs and rejected designs, such as a preferred aerodynamic profile for a requirement and a rejected aerodynamic profile for the same requirement. Design data 124, requirement data 125, design trajectory data 129, and design generative model 123 are stored in data store 120. In some embodiments, data store 120 can include any storage device or devices, such as fixed disc drive(s), flash drive(s), optical storage, network attached storage (NAS), and/or a storage area-network (SAN). Although shown as accessible over network 130, in at least one embodiment machine learning server 110 can include data store 120.

Processor(s) 142 receive user input from input devices, such as a keyboard or a mouse. Processor(s) 142 may include one or more primary processors of computing device 140, which control and coordinate operations of other system components. In particular, processor(s) 142 can issue commands that control the operation of one or more graphics processing units (GPUs) (not shown) and/or other parallel processing circuitry (e.g., parallel processing units, deep learning accelerators, etc.) that incorporates circuitry optimized for graphics and video processing, including, for example, video output circuitry. The GPU(s) can deliver pixels to a display device that can be any conventional cathode ray tube, liquid crystal display, light-emitting diode display, and/or similar technologies.

Memory 144 of computing device 140 stores content, such as software applications and data, for use by processor(s) 142 and the GPU(s) and/or other processing units. Memory 144 can be any type of memory capable of storing data and software applications, such as a random-access memory (RAM), a read-only memory (ROM), an erasable programmable read-only memory (EPROM or Flash ROM), or any suitable combination of the foregoing. In some embodiments, a storage (not shown) can supplement or replace memory 144. The storage can include any number and type of external memories that are accessible to processor(s) 142 and/or the GPU. For example, and without limitation, the storage can include a Secure Digital Card, an external Flash memory, a portable compact disc read-only memory (CD-ROM), an optical storage device, a magnetic storage device, and/or any suitable combination of the foregoing.

Computing device 140 shown herein is for illustrative purposes only, and variations and modifications are possible without departing from the scope of the present disclosure. For example, the number of processors 142, the number of GPUs and/or other processing unit types, the number of memories 144, and/or the number of applications included in memory 144 can be modified as desired. Further, the connection topology between the various units in FIG. 1 can be modified as desired. In some embodiments, any combination of processor(s) 142, memory 144, and/or GPUs can be included in and/or replaced with any type of virtual computing system, distributed computing system, and/or cloud computing environment, such as a public, private, or hybrid cloud system.

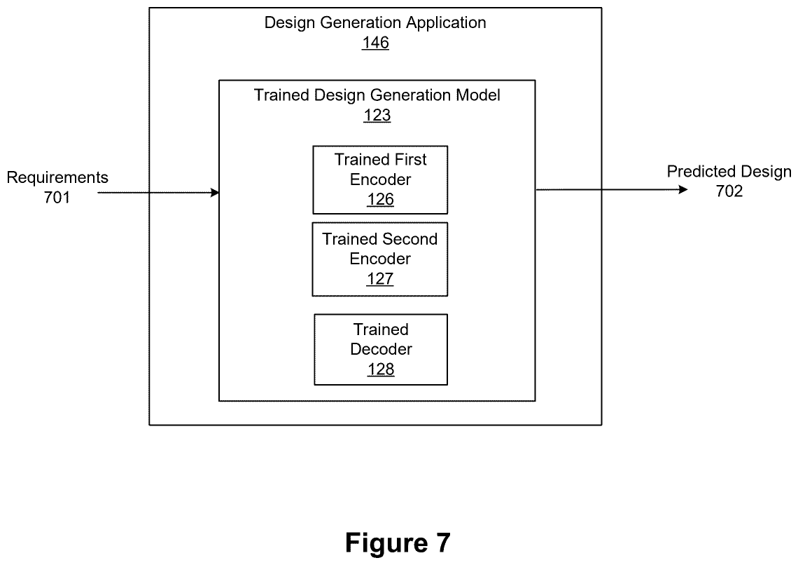

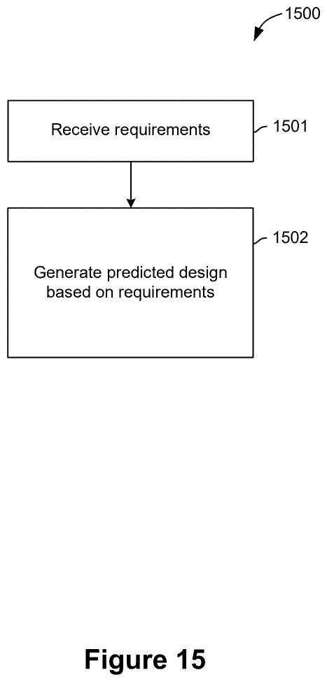

As shown, design generation application 146, which uses design generative models 123 stored in data store 120 and accessed over network 130, executes on processor(s) 142 of computing device 140. In some embodiments, design generation application 146 uses design generative models 123 to process the requirements and generate the predicted design. Design generation application 146 is described in greater detail herein at least in conjunction with FIGS. 7 and 15.

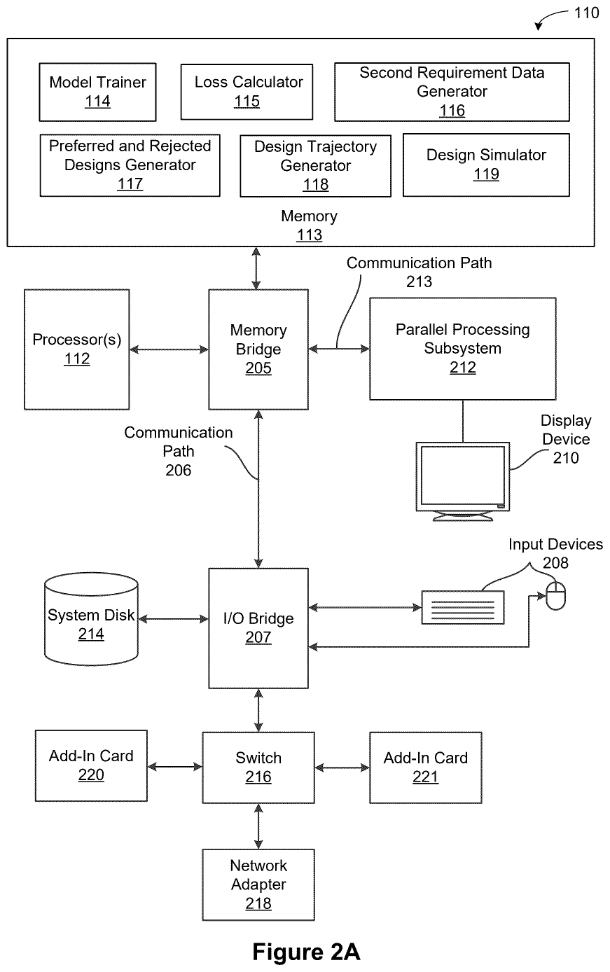

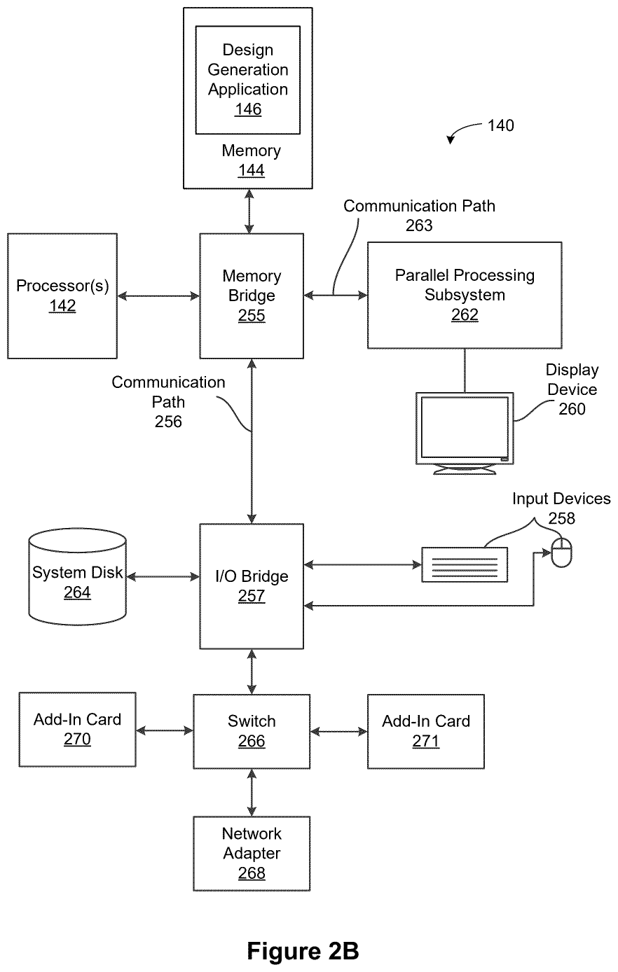

FIG. 2A is a more detailed illustration of machine learning server 110 of FIG. 1, according to various embodiments. Machine learning server 110 may include any type of computing system, including, without limitation, a server machine, a server platform, a desktop machine, a laptop machine, a handheld/mobile device, a digital kiosk, an in-vehicle infotainment system, and/or a wearable device. In some embodiments, machine learning server 110 is a server machine operating in a data center or a cloud computing environment that provides scalable computing resources as a service over a network.

In various embodiments, machine learning server 110 includes, without limitation, processor(s) 112 and memory (ies) 113 coupled to a parallel processing subsystem 212 via a memory bridge 205 and a communication path 213. Memory bridge 205 is further coupled to an I/O (input/output) bridge 207 via a communication path 206, and I/O bridge 207 is, in turn, coupled to a switch 216.

In some embodiments, I/O bridge 207 is configured to receive user input information from optional input devices 208, such as a keyboard, mouse, touch screen, or sensor data analysis (e.g., evaluating gestures, speech, or other information about one or more users in a field of view or sensory field of one or more sensors), and/or the like, and forward the input information to processor(s) 112 for processing. In some embodiments, machine learning server 110 may be a server machine in a cloud computing environment. In some embodiments, machine learning server 110 may not include input devices 208 but may receive equivalent input information by receiving commands (e.g., responsive to one or more inputs from a remote computing device) in the form of messages transmitted over a network and received via network adapter 218. In some embodiments, switch 216 is configured to provide connections between I/O bridge 207 and other components of machine learning server 110, such as a network adapter 218 and various add in cards 220 and 221.

In some embodiments, I/O bridge 207 is coupled to a system disk 214 that may be configured to store content and applications and data for use by processor(s) 112 and parallel processing subsystem 212. In some embodiments, system disk 214 provides non volatile storage for applications and data and may include fixed or removable hard disk drives, flash memory devices, and CD ROM (compact disc read only memory), DVD ROM (digital versatile disc ROM), Blu ray, HD DVD (high definition DVD), or other magnetic, optical, or solid state storage devices. In various embodiments, other components, such as universal serial bus or other port connections, compact disc drives, digital versatile disc drives, film recording devices, and the like, may be connected to I/O bridge 207 as well.

In various embodiments, memory bridge 205 may be a Northbridge chip, and I/O bridge 207 may be a Southbridge chip. In addition, communication paths 206 and 213, as well as other communication paths within machine learning server 110, may be implemented using any technically suitable protocols, including, without limitation, AGP (Accelerated Graphics Port), HyperTransport, or any other bus or point to point communication protocol known in the art.

In some embodiments, parallel processing subsystem 212 comprises a graphics subsystem that delivers pixels to an optional display device 210 that may be any conventional cathode ray tube, liquid crystal display, light emitting diode display, and/or the like. In some embodiments, parallel processing subsystem 212 may incorporate circuitry that is optimized for graphics and video processing, including, for example, video output circuitry. Such circuitry may be incorporated across one or more parallel processing units (PPUs), also referred to herein as parallel processors, included within parallel processing subsystem 212.

In some embodiments, parallel processing subsystem 212 incorporates circuitry that is optimized (e.g., that undergoes optimization) for general purpose and/or compute processing. Again, such circuitry may be incorporated across one or more PPUs included within parallel processing subsystem 212 that are configured to perform such general purpose and/or compute operations. In yet other embodiments, the one or more PPUs included within parallel processing subsystem 212 may be configured to perform graphics processing, general purpose processing, and/or compute processing operations. Memory 113 includes at least one device driver configured to manage the processing operations of the one or more PPUs within parallel processing subsystem 212. In addition, memory 113 includes, without limitation, model trainer 114, loss calculator 115, second requirement data generator 116, preferred and rejected designs generator 117, design trajectory generator 118, and design simulator 119. Although described herein primarily with respect to model trainer 114, loss calculator 115, second requirement data generator 116, preferred and rejected designs generator 117, design trajectory generator 118, and design simulator 119, techniques disclosed herein can also be implemented, either entirely or in part, in other software and/or hardware, such as in parallel processing subsystem 212.

In various embodiments, parallel processing subsystem 212 may be integrated with one or more of the other elements of FIG. 2A to form a single system. For example, parallel processing subsystem 212 may be integrated with processor(s) 112 and other connection circuitry on a single chip to form a system on a chip (SoC).

In some embodiments, processor(s) 112 includes the primary processor of machine learning server 110, controlling and coordinating operations of other system components. In some embodiments, processor(s) 112 issues commands that control the operation of PPUs. In some embodiments, communication path 213 is a PCI Express link, in which dedicated lanes are allocated to each PPU. Other communication paths may also be used. The PPU advantageously implements a highly parallel processing architecture, and the PPU may be provided with any amount of local parallel processing memory (PP memory).

It will be appreciated that the system shown herein is illustrative and that variations and modifications are possible. The connection topology, including the number and arrangement of bridges, the number of processor(s) 112, and the number of parallel processing subsystems 212, may be modified as desired. For example, in some embodiments, memory 113 could be connected to the processor(s) 112 directly rather than through memory bridge 205, and other devices may communicate with memory 113 via memory bridge 205 and processor(s) 112. In other embodiments, parallel processing subsystem 212 may be connected to I/O bridge 207 or directly to processor(s) 112, rather than to memory bridge 205. In still other embodiments, I/O bridge 207 and memory bridge 205 may be integrated into a single chip instead of existing as one or more discrete devices. In some embodiments, one or more components shown in FIG. 2A may not be present. For example, switch 216 could be eliminated, and network adapter 218 and add in cards 220, 221 would connect directly to I/O bridge 207. Lastly, in some embodiments, one or more components shown in FIG. 2A may be implemented as virtualized resources in a virtual computing environment, such as a cloud computing environment. In particular, parallel processing subsystem 212 may be implemented as a virtualized parallel processing subsystem in at least one embodiment. For example, parallel processing subsystem 212 may be implemented as virtual graphics processing unit(s) (vGPU(s)) that renders graphics on a virtual machine(s) (VM(s)) executing on a server machine(s) whose GPU(s) and other physical resources are shared across one or more VMs.

FIG. 2B is a more detailed illustration of computing device 140 of FIG. 1, according to various embodiments. Computing device 140 may include any type of computing system, including, without limitation, a server machine, a server platform, a desktop machine, a laptop machine, a handheld/mobile device, a digital kiosk, an in-vehicle infotainment system, and/or a wearable device. In some embodiments, computing device 140 is a server machine operating in a data center or a cloud computing environment that provides scalable computing resources as a service over a network. In some embodiments, computing device 140 can include one or more similar components as machine learning server 110.

In various embodiments, computing device 140 includes, without limitation, processor(s) 142 and memory (ies) 144 coupled to a parallel processing subsystem 262 via a memory bridge 255 and a communication path 263. Memory bridge 255 is further coupled to an I/O bridge 257 via a communication path 256, and I/O bridge 257 is, in turn, coupled to a switch 266.

In one embodiment, I/O bridge 257 is configured to receive user input information from optional input devices 258, such as a keyboard, mouse, touch screen, or sensor data analysis (e.g., evaluation of gestures, speech, or other information about one or more users in a field of view or sensory field of one or more sensors), and to forward the input information to processor(s) 142 for processing. In some embodiments, computing device 140 may be a server machine in a cloud computing environment. In such embodiments, computing device 140 may not include input devices 258 but may receive equivalent input information by receiving commands (e.g., responsive to one or more inputs from a remote computing device) in the form of messages transmitted over a network and received via network adapter 268. In some embodiments, switch 266 is configured to provide connections between I/O bridge 257 and other components of computing device 140, such as network adapter 268 and various add in cards 270 and 271.

In some embodiments, I/O bridge 257 is coupled to a system disk 264 that may be configured to store content and applications and data for use by processor(s) 142 and parallel processing subsystem 262. In one embodiment, system disk 264 provides non-volatile storage for applications and data and may include fixed or removable hard disk drives, flash memory devices, and CD-ROM (compact disc read-only-memory), DVD-ROM (digital versatile disc-ROM), Blu-ray, HD-DVD (high-definition DVD), or other magnetic, optical, or solid-state storage devices. In various embodiments, other components, such as universal serial bus or other port connections, compact disc drives, digital versatile disc drives, film recording devices, and similar components, may be connected to I/O bridge 257 as well.

In various embodiments, memory bridge 255 may be a Northbridge chip, and I/O bridge 257 may be a Southbridge chip. In addition, communication paths 256 and 263, as well as other communication paths within computing device 140, may be implemented using any technically suitable protocols, including, without limitation, AGP (Accelerated Graphics Port), HyperTransport, or any other bus or point to point communication protocol known in the art.

In some embodiments, parallel processing subsystem 262 comprises a graphics subsystem that delivers pixels to an optional display device 260 that may be any conventional cathode ray tube, liquid crystal display, light-emitting diode display, and/or similar technologies. In such embodiments, parallel processing subsystem 262 may incorporate circuitry optimized for graphics and video processing, including, for example, video output circuitry. Such circuitry may be incorporated across one or more parallel processing units (PPUs), also referred to herein as parallel processors, included within parallel processing subsystem 262.

In some embodiments, parallel processing subsystem 262 incorporates circuitry optimized for general purpose and/or compute processing. Again, such circuitry may be incorporated across one or more PPUs included within parallel processing subsystem 262, which are configured to perform such general-purpose and/or compute operations. In yet other embodiments, the one or more PPUs included within parallel processing subsystem 262 may be configured to perform graphics processing, general-purpose processing, and/or compute processing operations. System memory 144 includes at least one device driver configured to manage the processing operations of the one or more PPUs within parallel processing subsystem 262. In addition, system memory 144 includes design generation application 146. Although described herein primarily with respect to design generation application 146, techniques disclosed herein can also be implemented, either entirely or in part, in other software and/or hardware, such as in parallel processing subsystem 262.

In various embodiments, parallel processing subsystem 262 may be integrated with one or more of the other elements of FIG. 2B to form a single system. For example, parallel processing subsystem 262 may be integrated with processor(s) 142 and other connection circuitry on a single chip to form a system on a chip (SoC).

In some embodiments, processor(s) 142 includes the primary processor of computing device 140, controlling and coordinating operations of other system components. In some embodiments, processor(s) 142 issue commands that control the operation of PPUs. In some embodiments, communication path 263 is a PCI Express link, in which dedicated lanes are allocated to each PPU. Other communication paths may also be used. The PPU advantageously implements a highly parallel processing architecture, and the PPU may be provided with any amount of local parallel processing memory (PP memory).

It will be appreciated that the system shown herein is illustrative and that variations and modifications are possible. The connection topology, including the number and arrangement of bridges, the number of processor(s) 142, and the number of parallel processing subsystems 262, may be modified as desired. For example, in some embodiments, system memory 144 could be connected to processor(s) 142 directly rather than through memory bridge 255, and other devices may communicate with system memory 144 via memory bridge 255 and processor(s) 142. In other embodiments, parallel processing subsystem 262 may be connected to I/O bridge 257 or directly to processor(s) 142, rather than to memory bridge 255. In still other embodiments, I/O bridge 257 and memory bridge 255 may be integrated into a single chip instead of existing as one or more discrete devices. In some embodiments, one or more components shown in FIG. 2B may not be present. For example, switch 266 could be eliminated, and network adapter 268 and add-in cards 270, 271 would connect directly to I/O bridge 257. Lastly, in some embodiments, one or more components shown in FIG. 2B may be implemented as virtualized resources in a virtual computing environment, such as a cloud computing environment. In particular, parallel processing subsystem 262 may be implemented as a virtualized parallel processing subsystem in at least one embodiment. For example, parallel processing subsystem 262 may be implemented as virtual graphics processing unit(s) (vGPU(s)) that renders graphics on virtual machine(s) (VM(s)) executing on server machine(s) whose GPU(s) and other physical resources are shared across one or more VMs.

### Training Design Generative Model Based on Requirement-Satisfying Designs

FIG. 3A is a more detailed illustration of design simulator 119 generating design data 124, according to various embodiments. As shown, design generative model 123 includes first encoder 126 and decoder 128. Design data 124 includes requirement-satisfying designs 303. In operation, design generative model 123 processes requirements 301 included in requirement data 125 and generates designs 302. Design simulator 119 simulates designs 302 and determines requirement-satisfying designs 303 based on requirements 301. Design simulator 119 stores requirement-satisfying designs 303 in design data 124.

Design generative model 123 processes requirements 301 and generates designs 302. In some embodiments, design generative model 123 includes a generative model for engineering design, such as GearFormer and/or the like, which is trained on a synthetic dataset. In some examples, the synthetic dataset can be constructed by generating candidate designs x using procedural rules, design grammars, parametric sampling, or other non-simulation-based initialization techniques. Design generative model 123 includes first encoder 126 and decoder 128. First encoder 126 is a trained machine learning model, such as a neural network, that processes requirements 301 and generates a requirement embedding. In some examples, first encoder 126 can include a multilayer perceptron (MLP), a transformer-based encoder, a recurrent neural network (RNN), or a convolutional neural network (CNN). Decoder 128 is another trained machine learning model, such as a neural network, that processes the requirement embedding and generates designs 302. In some embodiments, decoder 128 includes a generative decoder, such as a variational autoencoder (VAE) decoder, a diffusion-model denoising network, a transformer-based autoregressive generator, or a graph neural network (GNN) decoder configured to generate geometric models, component assemblies, parametric configurations, mesh structures, or other digital design representations corresponding to the requirement embedding.

Design simulator 119 simulates designs 302 and determines requirement-satisfying designs 303 based on requirements 301. In some embodiments, design simulator 119 performs one or more simulations, such as a physics-based simulation, a finite-element analysis, a computational fluid dynamics simulation, a thermal or energy-transfer simulation, an electrical circuit simulation, and/or the like, depending on each design 302. For example, when designs 302 correspond to structural components, design simulator 119 can evaluate stress, strain, deformation, or load distribution. When designs 302 correspond to aerodynamic surfaces, design simulator 119 can evaluate lift, drag, or flow behavior. When designs 302 correspond to electronic or thermal systems, design simulator 119 can evaluate heat dissipation, temperature gradients, or power consumption. Based on the simulation results, design simulator 119 determines a requirement-satisfying design 303 as a design 302 that achieves a performance value within a threshold associated with each requirement 301. In some examples, design simulator 119 can evaluate each generated design 302 and compute a corresponding requirement value vector \vec{r}. In some examples, design simulator 119 computes, for each design 302, a simulated requirement-value vector \vec{r}ₛᵢₘ (design)=(r_{sim,1}, r_{sim,2}, . . . , r_{sim,k}), where each r_{sim,i} is the simulated performance value corresponding to requirement 301 rᵢ. In some examples, design simulator 119 determines a requirement-satisfying design 303 when the simulated requirement values satisfy a requirement condition of at least one of the following forms r_{sim,i}≈rᵢ or r_{sim,i}≥rᵢ or r_{sim,i}≤rᵢ, depending on whether the requirement specifies a target-value condition, a minimum-value condition, or a maximum-value condition. For example, when designs 302 include structural components, design simulator 119 can compute stress or strain values and determine whether such stress or strain values satisfy the stress requirement rᵢ; when designs 302 include aerodynamic surfaces, design simulator 119 can compute lift or drag and determine whether the simulated values meet aerodynamic requirement rᵢ. In some embodiments, design simulator 119 evaluates each generated design 302 by computing the simulated requirement value vector \vec{r}ₛᵢₘ and identifies the requirement-satisfying designs 303 as designs for which the simulated requirement values meet or exceed the requirement thresholds rᵢ included in requirements 301. In some embodiments, design simulator 119 stores requirement-satisfying designs 303 in design data 124. In some embodiments, design simulator 119 continues generating requirement-satisfying designs 303 until one or more stopping criteria are met, such as reaching a fixed number of requirement-satisfying designs 303.

FIG. 3B is a more detailed illustration of model trainer 114 training design generative model 123 based on design data 124, according to various embodiments. As shown, design generative model 123 includes first encoder 126 and decoder 128. In operation, design generative model 123 processes requirements 310 included in requirement data 125 and generates predicted designs 312. Loss calculator 115 calculates loss 314 based on predicted designs 312 and requirement-satisfying designs 303. Model trainer 114 updates one or more parameters of decoder 128 based on loss 314 iteratively until one or more stopping criteria are met.

Design generative model 123 processes requirements 310 and generates predicted designs 312. First encoder 126 processes requirements 310 and generates a requirement embedding. Decoder 128 processes the requirement embedding and generates predicted designs 312. In some embodiments, decoder 128 includes a generative decoder configured to generate geometric models, component assemblies, parametric configurations, mesh structures, or other digital design representations corresponding to the requirement embedding.

Loss calculator 115 calculates loss 314 based on predicted designs 312 and requirement-satisfying designs 303. In some embodiments, loss calculator 115 computes loss 314 by comparing predicted designs 312 generated by design generative model 123 against requirement-satisfying designs 303. For example, loss 314 can include a log-probability loss and/or a similar loss. In some embodiments, loss calculator 115 calculates the log-probability loss that encourages design generative model 123 to increase the likelihood of generating requirement-satisfying designs 303. In some examples, the log-probability loss can be calculated as:

$$ℒ ( θ ) = - {𝔼}_{{x}^{′} ∼ {π}_{θ}} [ log {π}_{θ} ( {x}^{′} \vert {r}_{i} ) ] , \qquad ( Equation 1 )$$

where π_{θ} denotes the parameterized design generative model 123, x′ denotes a predicted design 312 sampled from π_{θ}, and rᵢ denotes the requirement 310 of interest.

In some embodiments, model trainer 114 updates the one or more parameters of decoder 128 based on loss 314. In some embodiments, model trainer 114 updates decoder 128 using gradient-based optimization techniques, such as stochastic gradient descent (SGD), adaptive moment estimation (Adam), root mean square propagation (RMSProp), and/or similar optimization techniques. In at least one embodiment, model trainer 114 keeps first encoder 126 fixed during training and updates only decoder 128 so that the learned requirement embedding generated by first encoder 126 remains stable while decoder 128 adapts to generate requirement-satisfying designs 303. In some embodiments, model trainer 114 iteratively updates decoder 128 over multiple training steps until meeting one or more convergence conditions, such as reaching a maximum number of training steps (e.g., 19 steps), loss 314 falling below a threshold value, loss 314 stabilizing across successive iterations, satisfying a simulator-defined performance criterion, and/or similar convergence conditions.

### Training Design Generative Model Based on First Requirement Data and Second Requirement Data

FIG. 4A is a more detailed illustration of second requirement data generator 116, according to various embodiments. As shown, second requirement data generator 116 includes design generative model 123 and a second requirement bound value generator 420. Design generative model 123 includes first encoder 126 and decoder 128. Second requirement bound value generator 420 includes design simulator 119. Requirement data 125 includes first requirement data 421 and second requirement data 422. In operation, design generative model 123 processes requirements 401 included in first requirement data 421 and generates design 402, which is stored in design data 124. Second requirement bound value generator 420 uses design simulator to simulate designs 402 and generate second requirement bound values 405 based on second requirements 404.

Design generative model 123 processes requirements 401 included in first requirement data 421 and generates design 402. In some embodiments, first requirement data 421 includes requirements 401 that design generative model 123 was trained on. First encoder 126 processes requirements 401 and generates a first requirement embedding. Decoder 128 processes the first requirement embedding and generates design 402. In some embodiments, decoder 128 includes a generative decoder configured to generate geometric models, component assemblies, parametric configurations, mesh structures, or other digital design representations corresponding to the requirement embedding. In some embodiments, design generative model 123 stores design 402 in design data 124.

Second requirement bound value generator 420 is an application or a module of second requirement data generator 116 that uses design simulator 119 to process design 402 and second requirement 404 and generate second requirement bound value 405. In some embodiments, second requirement 404 n; received from one or more I/O devices (not shown) includes a new requirement that design generative model 123 was not trained on. In some examples, second requirement bound value generator 420 computes a requirement value N_{i,sim}(x) for design 402 x using design simulator 119, and then perturbs the requirement value with a random variance σ to generate a bound value

$${\tilde{N}}_{i} \leq {N}_{i , sim} ( x ) + σ . \qquad ( Equation 2 )$$

In some examples, second requirement bound value generator 420 synthetically generates a pair (Ñᵢ, x), where Ñᵢ serves as a constraint or requirement value associated with second requirement 404 nᵢ, and design 402 x is treated as a design that satisfies the bound described in Equation 2. In some embodiments, second requirement data generator 116 stores second requirement bound value 405 and second requirement 404 in second requirement data 422, which is included in requirement data 125.

FIG. 4B is a more detailed illustration of model trainer 114 training design generative model 123 based on first requirement data 421 and second requirement data 422, according to various embodiments. As shown, design generative model 123 includes first encoder 126, second encoder 127, and decoder 128. Requirement data 125 includes first requirement data 421 and second requirement data 422. In operation, design generative model 123 processes first requirement data 421 and second requirement data 422 and generates predicted design 410. Loss calculator 115 calculates loss 411 based on design data 124 and predicted design 410. Model trainer 114 iteratively updates the parameters of second encoder 127 and decoder 128 based on loss 411 until one or more stopping criteria are met.

Design generative model 123 processes first requirement data 421 and second requirement data 422 and generates predicted design 410. First encoder 126 processes requirements included in first requirement data 421 and generates a first requirement embedding. Second encoder 127 is a machine learning model, such as a neural network, that processes one or more second requirements included in second requirement data 422 and generates a second requirement embedding. Decoder 128 processes at least one of the first requirement embedding and the second requirement embedding and generates predicted design 410. In some embodiments, decoder 128 includes a generative decoder configured to generate geometric models, component assemblies, parametric configurations, mesh structures, or other digital design representations corresponding to at least one of the first requirement embedding or the second requirement embedding.

Loss calculator 115 calculates loss 411 based on predicted design 410 and design data 124. In some embodiments, loss calculator 115 computes loss 411 by comparing predicted design 410 generated by design generative model 123 against a design included in design data 124. For example, loss 411 can include a log-probability loss and/or the like. In some embodiments, loss calculator 115 calculates the log-probability loss that encourages design generative model 123 to increase the likelihood of generating the design included in design data 124. In some examples, the log-probability loss can be calculated as given in Equation 1.

In some embodiments, model trainer 114 updates the one or more parameters of second encoder 127 and decoder 128 based on loss 411. In some embodiments, model trainer 114 updates second encoder 127 and decoder 128 using gradient-based optimization techniques, such as SGD, Adam, RMSProp, and/or the like. In at least one embodiment, model trainer 114 keeps first encoder 126 fixed during training and updates only second encoder 127 and decoder 128. In some embodiments, model trainer 114 iteratively updates second encoder 127 and decoder 128 over multiple training steps until meeting one or more convergence conditions, such as reaching a maximum number of training steps (e.g., 6 steps or 10 steps), loss 411 falling below a threshold value, loss 411 stabilizing across successive iterations, satisfying a simulator-defined performance criterion, and/or the like.

### Training Design Generative Model Based on Preferred Designs and Rejected Designs

FIG. 5A is a more detailed illustration of the preferred and rejected designs generator 117 of FIG. 1, according to various embodiments. As shown, design data 124 includes preferred designs 522 and rejected designs 521. Design generative model 123 includes first encoder 126, second encoder 127, and decoder 128. In operation, design generative model 123 processes requirements 501 included in requirement data 125 and generates designs 502. Design simulator 119 simulates designs 502 and determines design performance values 503 based on requirements 501. Preferred and rejected designs generator 117 processes designs 502 and design performance values 503 and generates preferred designs 522 and rejected designs 521.

Design generative model 123 processes requirements 501 included in requirement data 125 and generates designs 502. In some embodiments, at least one of first encoder 126 or second encoder 127 processes requirements 501 and generates a requirement embedding. Decoder 128 processes the requirement embedding and generates designs 502. In some embodiments, decoder 128 includes a generative decoder configured to generate geometric models, component assemblies, parametric configurations, mesh structures, or other digital design representations corresponding to the requirement embedding. In some embodiments, design generative model 123 stores design 402 in design data 124.

Design simulator 119 simulates designs 502 and determines design performance values 503 based on requirements 501. In some embodiments, design simulator 119 performs one or more simulations, such as a physics-based simulation, a finite-element analysis, a computational fluid dynamics simulation, a thermal or energy-transfer simulation, an electrical circuit simulation, and/or the like, depending on each design 502. For example, when designs 502 correspond to structural components, design simulator 119 can evaluate stress, strain, deformation, or load distribution. When designs 502 correspond to aerodynamic surfaces, design simulator 119 can evaluate lift, drag, or flow behavior. When designs 502 correspond to electronic or thermal systems, design simulator 119 can evaluate heat dissipation, temperature gradients, or power consumption. For example, for a given requirement 501 of interest rᵢ, design simulator 119 can compute a requirement performance value 503 N_{i,sim}(x) for each design 502 x.

Preferred and rejected designs generator 117 processes designs 502 and design performance values 503 and generates preferred designs 522 and rejected designs 521. In some embodiments, preferred and rejected designs generator 117 ranks designs 502 based on design performance values 503 returned by design simulator 119. In some examples, for three designs 502 x⁽¹⁾, x⁽²⁾, and x⁽³⁾, preferred and rejected designs generator 117 can order designs 502 based on the design performance values 503, such as N_{i,sim}(x⁽¹⁾)<N_{i,sim}(x⁽²⁾)<N_{i,sim}(x⁽³⁾), where designs 502 with lower performance values satisfy the requirement more effectively. In some embodiments, preferred and rejected designs generator 117 identifies at least one preferred design 520, such as the design achieving the lowest requirement performance value 503, and at least one rejected design 521, such as the design achieving a higher performance value. In some examples, preferred and rejected designs generator 117 determines a constraint bound value using μ=μ(N_{i,sim}(x^{(p)}), N_{i,sim}(x^{(r)}), where x^{(p)} denotes the preferred design 522 and x^{(r)} denotes the rejected design 521, and μ(⋅) includes a mean or averaging function. In some embodiments, preferred design 522 satisfies the constraint bound Nᵢ≤μ while rejected design 521 does not satisfy the constraint. In some embodiments, preferred and rejected designs generator 117 stores preferred designs 522 and rejected designs 521 in design data 124.

FIG. 5B is a more detailed illustration of model trainer 114 training design generative model 123 based on preferred designs 522 and rejected designs 521, according to various embodiments. As shown, design generative model 123 includes first encoder 126, second encoder 127, and decoder 128. Design data 124 includes rejected designs 521 and preferred designs 522. In operation, design generative model 123 processes requirement data 125 and generates predicted design 510. Loss calculator 115 calculates loss 511 based on predicted designs 510, rejected designs 521, and preferred designs 522. Model trainer 114 updates the one or more parameters of decoder 128 based on loss 511 until one or more stopping criteria are met.

Design generative model 123 processes requirements included in requirement data 125 and generates predicted designs 510. In some embodiments, at least one of first encoder 126 or second encoder 127 processes the requirements and generates a requirement embedding. Decoder 128 processes the requirement embedding and generates predicted designs 510. In some embodiments, decoder 128 includes a generative decoder configured to generate geometric models, component assemblies, parametric configurations, mesh structures, or other digital design representations corresponding to the requirement embedding.

Loss calculator 115 calculates loss 511 based on predicted design 510, rejected designs 521, and preferred designs 522. In some embodiments, loss calculator 115 computes loss 511 using a direct preference optimization (DPO) loss that encourages design generative model 123 to increase the likelihood of generating preferred designs 522 relative to rejected designs 521 for a given requirement. For example, the DPO loss can be calculated as:

$${ℒ}_{DPO} ( θ ) = - {𝔼}_{( {x}_{w} , {x}_{l} , {n}_{i} ) ∼ D} [ log σ ( β log \frac{{π}_{θ} ( {x}_{w} \vert {n}_{i} )}{{π}_{old} ( {x}_{w} \vert {n}_{i} )} - β log \frac{{π}_{θ} ( {x}_{l} \vert {n}_{i} )}{{π}_{old} ( {x}_{l} \vert {n}_{i} )} ) ] , \qquad ( Equation 3 )$$

where x_{w} denotes a preferred design 522, x₁ denotes a rejected design 521, nᵢ denotes the requirement included in requirement data 125 under which preferred design 522 and rejected design 521 pair was evaluated, π_{θ} denotes the current design generative model 123, π_{old} denotes a reference model or previous checkpoint of design generative model 123, and β is a scaling factor (e.g., β=0.1) for the Kullback-Leibler divergence penalty. In some embodiments, loss calculator 115 computes loss 511 by evaluating the log-probabilities of preferred designs 522 and rejected designs 521 generated by design generative model 123 and weighting the log likelihoods according to Equation 3. In some examples, the previous checkpoint of design generative model 123 can be picked post hoc, subject to the criterion that a fixed percentage, such as % 95, of the predicted design 510 are valid.

In some embodiments, model trainer 114 updates the one or more parameters of decoder 128 based on loss 511. In some embodiments, model trainer 114 updates decoder 128 using gradient-based optimization techniques, such as SGD, Adam, RMSProp, and/or the like. In at least one embodiment, model trainer 114 keeps first encoder 126 and second encoder 127 fixed during training and updates only decoder 128. In some embodiments, model trainer 114 iteratively updates decoder 128 over multiple training steps until meeting one or more convergence conditions, such as reaching maximum number of training steps (e.g., 20 steps), loss 511 falling below a threshold value, loss 511 stabilizing across successive iterations, satisfying a simulator-defined performance criterion, and/or the like.

### Training Design Generative Model Based on Design Trajectory Data

FIG. 6A is a more detailed illustration of design trajectory generator 118, according to various embodiments. As shown, design trajectory generator 118 includes design generative model 123 and a design reward generator 620. Design generative model 123 includes first encoder 126, second encoder 127, and decoder 128. Design reward generator 620 includes design simulator 119. In operation, design generative model 123 processes requirements 601 included in requirement data 125 and generates designs 602. Design reward generator 620 uses design simulator 119 to simulate designs 602 and generate design rewards 603 based on requirements 601. Design trajectory generator 118 stores designs 602 and design rewards 603 in design trajectory data 129.

Design generative model 123 processes requirements 601 included in requirement data 125 and generates designs 602. In some embodiments, requirement data 125 includes first requirement data 421 and second requirement data 422. In some embodiments, at least one of first encoder 126 or second encoder 127 process requirements 601 and generate a requirement embedding. Decoder 128 processes the requirement embedding and generates designs 602. In some embodiments, decoder 128 includes a generative decoder configured to generate geometric models, component assemblies, parametric configurations, mesh structures, or other digital design representations corresponding to the requirement embedding.

Design reward generator 620 is a module of design trajectory generator 118 that uses design simulator 119 to simulate designs 602 and generate design rewards 603 based on requirements 601. In some embodiments, each requirement 601 rᵢ includes a target requirement bound value nᵢ. Design simulator 119 evaluates each design 602 x and computes an evaluated requirement value ñ(x), which indicates how well design 602 x satisfies requirement 601 rᵢ. In some embodiments, design reward generator 620 computes a reward value R(x,nᵢ) for each design 602 x using a simulator-based reward function normalized to the interval [−1,1]. For example, design reward generator 620 can compute design rewards 603 according to:

$$R ( x , {n}_{i} ) = \{ \text{} \begin{matrix}1 , & if \tilde{n} ( x ) \leq {n}_{i} , \\ 1 - \frac{2 ( \tilde{n} ( x ) - {n}_{i} )}{1 + ( \tilde{n} ( x ) - {n}_{i} )} , & otherwise\end{matrix} , \text{} \qquad ( Equation 4 )$$

where nᵢ is the target requirement bound and ñ(x) is the evaluated requirement value returned by design simulator 119. In Equation 4, a design 602 that satisfies the requirement (ñ(x)≤nᵢ) receives a reward of +1, while designs 602 that violate the requirement receive a reward approaching −1 as the magnitude of the violation increases. In some examples, design reward generator 620 computes design rewards 603 using a binary rule described as

$$R ( x , {n}_{i} ) = \{ \text{} \begin{matrix}+ 1 , & if \tilde{n} ( x ) \leq {n}_{i} \\ - 1 , & otherwise\end{matrix} , \text{} \qquad ( Equation 5 )$$

or another simulator-defined function that quantifies design performance relative to requirement 601. In some embodiments, design trajectory generator 118 stores designs 602 together with the corresponding design rewards 603 in design trajectory data 129.

FIG. 6B is a more detailed illustration of model trainer 114 training design generative model 123 based on design trajectory data 129, according to various embodiments. As shown, design generative model 123 includes first encoder 126, second encoder 127, and decoder 128. In operation, design generative model 123 processes requirements 601 included in requirement data 125 and generates predicted designs 611. Loss calculator 115 calculates loss 612 based on design trajectories 610 included in design trajectory data 129 and predicted designs 611. Model trainer 114 iteratively updates the parameters of decoder 128 based on loss 612 until one or more stopping criteria are met.

Design generative model 123 processes requirements included in requirement data 125 and generates predicted designs 611. In some embodiments, at least one of first encoder 126 or second encoder 127 process the requirements and generates a requirement embedding. Decoder 128 processes the requirement embedding and generates predicted designs 611. In some embodiments, decoder 128 includes a generative decoder configured to generate geometric models, component assemblies, parametric configurations, mesh structures, or other digital design representations corresponding to the requirement embedding.

Loss calculator 115 calculates loss 612 based on design trajectories 610 included in design trajectory data 129 and predicted designs 611. In some embodiments, each design trajectory 610 includes a sequence of generated designs 602 and the corresponding design rewards 603. In some embodiments, loss calculator 115 calculates loss 612 using a proximal-policy-optimization (PPO) objective. The PPO loss encourages design generative model 123 to increase the probability of generating designs 602 that achieve higher simulator design rewards 603 while preventing overly large updates that could destabilize training. In some examples, loss calculator 115 calculates loss 612 according to:

$${ℒ}_{RL} ( θ ) = - {𝔼}_{( x , {n}_{i} ) ∼ D} [ min ( \frac{{π}_{θ} ( x \vert {n}_{i} )}{{π}_{old} ( x \vert {n}_{i} )} R ( x , {n}_{i} ) , clip \frac{{π}_{θ} ( x \vert {n}_{i} )}{{π}_{old} ( x \vert {n}_{i} )} , 1 - ϵ , 1 + ϵ ) R ( x , {n}_{i} ) ) - β KL ( {π}_{θ} , {π}_{old} ) ] , \qquad ( Equation 6 )$$

where x denotes a design 602, nᵢ denotes the requirement bound value or threshold associated with requirement 601 i, π_{θ}(x|nᵢ) denotes the probability that design generative model 123 (with parameters θ) at the current iteration generates design 602 x given requirement 601 nᵢ, π_{old} (x|nᵢ) denotes the corresponding probability under the previous checkpoint of design generative model 123, R(x, nᵢ) is the simulator-generated design reward 603 for design 602 x relative to requirement 601 nᵢ, normalized to the range [−1,1], ε is a clipping parameter, such as 0.1 or 0.2, KL (π_{θ}, π_{old}) denotes a Kullback-Leibler divergence penalty that encourages the updated policy to remain close to the previous policy, and B is a regularization parameter (e.g., β=0.1) controlling the Kullback-Leibler divergence penalty strength. The clip function clip (z, 1−ε, 1+ε) restricts the policy ratio

$$z - \frac{{π}_{θ} ( x \vert {n}_{i} )}{{π}_{old} ( x \vert {n}_{i} )}$$

to remain within the interval 1−ε≤z≤1+ε, which prevents excessively large or unstable updates by ensuring that probability ratios cannot grow or shrink beyond a controlled range. When the ratio attempts to exceed the upper or lower bound, the ratio is replaced by the clipped value. In Equation 6, the term that includes design reward 603 R(x, nᵢ) encourages high-performing designs 602, while the Kullback-Leibler divergence penalty term prevents the updated design generative model 123 from deviating too far from the previous checkpoint version of design generative model 123.

In some embodiments, model trainer 114 iteratively updates the parameters of decoder 128 based on loss 612. In some embodiments, model trainer 114 updates decoder 128 using gradient-based optimization techniques, such as SGD, Adam, RMSProp, and/or the like. In at least one embodiment, model trainer 114 keeps first encoder 126 and second encoder 127 fixed during training and updates only decoder 128. In some embodiments, model trainer 114 iteratively updates decoder 128 over multiple training steps until meeting one or more convergence conditions, such as reaching maximum number of training steps (e.g., 20 steps), loss 612 falling below a threshold value, loss 612 stabilizing across successive iterations, satisfying a simulator-defined performance criterion, and/or the like.

### Design Generation Using Trained Design Generative Model

FIG. 7 is a more detailed illustration of design generation application 146, according to various embodiments. As shown, design generation application 146 includes trained design generation model 123. In operation, trained design generation model 123 processes requirements 701 and generates predicted design 702.

Trained design generative model 123 processes requirements 701 and generates predicted design 702. In some embodiments, requirements 701 are received from one or more I/O devices, such as user inputs, application programming interfaces (APIs), graphical user interfaces (GUIs), automated design pipelines, and/or external software systems. In some examples, requirements 701 can include one or more requirement values that define the design objectives, constraints, or operating conditions predicted design 702 must satisfy. In some embodiments, at least one of trained first encoder 126 or trained second encoder 127 processes requirements 701 and generates a requirement embedding. Trained decoder 128 processes the requirement embedding and generates predicted design 702. In some embodiments, predicted design 702 includes a digital design representation satisfying requirements 701 to a degree learned during training. In some embodiments, predicted design 702 includes a geometric model, a parametric configuration, a component assembly, or any other structured design output generated by trained decoder 128.

FIG. 8 is a flow diagram of method steps for generating requirement-satisfying designs 303, according to various embodiments. Although the method steps are described in conjunction with the systems of FIGS. 1-7, persons skilled in the art will understand that any system configured to perform the method steps in any order falls within the scope of the present embodiments.

As shown, a method 800 begins with step 801, where design generative model 123 receives requirements 301 included in requirement data 125. In some embodiments, requirement data 125 includes one or more requirements 301 and corresponding requirement values that define the design objectives and constraints for design generation.

At step 802, design generative model 123 generates designs 302 based on requirements 301 included in requirement data 125. In some embodiments, design generative model 123 includes a generative model for engineering design, such as GearFormer and/or the like, which is trained on a synthetic dataset. Design generative model 123 includes first encoder 126 and decoder 128. First encoder 126 processes requirements 301 and generates a requirement embedding. Decoder 128 processes the requirement embedding and generates designs 302. In some embodiments, decoder 128 includes a generative decoder, such as a VAE decoder, a diffusion-model denoising network, a transformer-based autoregressive generator, or a GNN decoder configured to generate geometric models, component assemblies, parametric configurations, mesh structures, or other digital design representations corresponding to the requirement embedding.

At step 803, design simulator 119 determines requirement-satisfying designs 303 based on designs 302 and requirements 301. In some embodiments, design simulator 119 performs one or more simulations, such as a physics-based simulation, a finite-element analysis, a computational fluid dynamics simulation, a thermal or energy-transfer simulation, an electrical circuit simulation, and/or the like, depending on each design 302. Based on the simulation results, design simulator 119 determines a requirement-satisfying design 303 as a design 302 that achieves a performance value within a threshold associated with each requirement 301. In some examples, design simulator 119 can evaluate each generated design 302 and compute a corresponding requirement value vector \vec{r}. In some examples, design simulator 119 computes, for each design 302, a simulated requirement-value vector \vec{r}ₛᵢₘ (design)=(r_{sim,1}, r_{sim,2}, . . . , r_{sim, k}), where each r_{sim,i} is the simulated performance value corresponding to requirement 301 rᵢ. In some examples, design simulator 119 determines a requirement-satisfying design 303 when the simulated requirement values satisfy a requirement condition of at least one of the following forms r_{sim,i}≈rᵢ Or r_{sim,i}≥rᵢ or r_{sim,i}≤rᵢ, depending on whether the requirement specifies a target, minimum, or maximum value. In some embodiments, design simulator 119 evaluates each generated design 302 by computing a simulated requirement value vector \vec{r}ₛᵢₘ, which includes the performance values obtained from simulation. Design simulator 119 then identifies requirement-satisfying designs 303 as the designs whose simulated requirement value r_{sim,i} for each requirement meets or exceeds the corresponding requirement threshold rᵢ included in requirements 301. In some embodiments, design simulator 119 continues generating requirement-satisfying designs 303 until one or more stopping criteria are met, such as reaching a fixed number of requirement-satisfying designs 303.

At step 804, design simulator 119 stores requirement-satisfying designs 303 in design data 124.

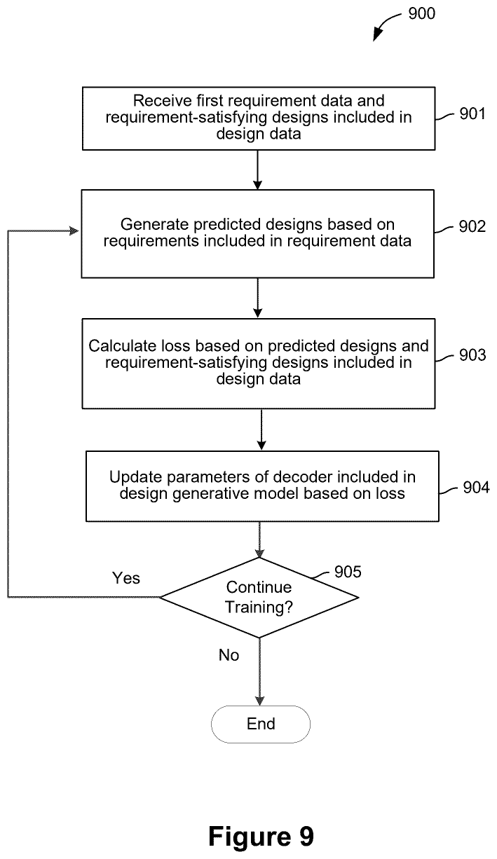

FIG. 9 is a flow diagram of method steps for training design generative model 123 based on requirement-satisfying designs 303, according to various embodiments. Although the method steps are described in conjunction with the systems of FIGS. 1-7, persons skilled in the art will understand that any system configured to perform the method steps in any order falls within the scope of the present embodiments.

As shown, a method 900 begins with step 901, where design generative model 123 receives requirement data 125 and requirement-satisfying designs 303 included in design data 124. In some embodiments, requirement data 125 includes one or more requirements 301 and corresponding requirement values that define the design objectives and constraints for design generation. In some embodiments, design data 124 includes one or more designs. For example, design data 124 can include geometric CAD meshes, parametric component configurations, mechanical assemblies, electrical layouts, structural topologies, 3D surface representations, and/or the like. In some embodiments, design data 124 includes requirement-satisfying designs 303, such as wing shapes that meet a specified lift-to-drag ratio, battery enclosures that meet thermal constraints, or bracket geometries that satisfy structural stiffness targets.

At step 902, design generative model 123 generates predicted designs 312 based on requirements 310 included in requirement data 125. In some embodiments, first encoder 126 processes requirements 310 and generates a requirement embedding. Decoder 128 processes the requirement embedding and generates predicted designs 312. In some embodiments, decoder 128 includes a generative decoder configured to generate geometric models, component assemblies, parametric configurations, mesh structures, or other digital design representations corresponding to the requirement embedding.

At step 903, loss calculator 115 calculates loss 314 based on predicted designs 312 and requirement-satisfying designs 303 included in design data 124. In some embodiments, loss calculator 115 computes loss 314 by comparing predicted designs 312 generated by design generative model 123 against requirement-satisfying designs 303. For example, loss 314 can include a log-probability loss and/or the like. In some embodiments, loss calculator 115 calculates the log-probability loss that encourages design generative model 123 to increase the likelihood of generating requirement-satisfying designs 303. In some examples, the log-probability loss can be calculated as described in Equation 1.

At step 904, model trainer 114 updates parameters of decoder 128 included in design generative model 123 based on loss 314. In some embodiments, model trainer 114 updates decoder 128 using gradient-based optimization techniques, such as SGD, Adam, RMSProp, and/or the like. In at least one embodiment, model trainer 114 keeps first encoder 126 fixed during training and updates only decoder 128 so that the learned requirement embedding generated by first encoder 126 remains stable while decoder 128 adapts to generate requirement-satisfying designs 303.

At step 905, model trainer 114 determines whether to continue training. In some embodiments, model trainer 114 iteratively updates decoder 128 over multiple training steps until meeting one or more convergence conditions, such as reaching a maximum number of training steps (e.g., 19 steps), loss 314 falling below a threshold value, loss 314 stabilizing across successive iterations, satisfying a simulator-defined performance criterion, and/or the like. When model trainer 114 determines to continue training, method 900 returns to step 902. When model trainer 114 determines not to continue training, method 900 terminates.

FIG. 10 is a flow diagram of method steps for generating second requirement data 422, according to various embodiments. Although the method steps are described in conjunction with the systems of FIGS. 1-7, persons skilled in the art will understand that any system configured to perform the method steps in any order falls within the scope of the present embodiments.

As shown, a method 1000 begins with step 1001, where design generative model 123 receives first requirement data 421 and second requirement bound value generator 420 receives second requirement 404. In some embodiments, first requirement data 421 includes requirements 401 that design generative model 123 was trained on. In some embodiments, second requirement 404 nᵢ received from one or more I/O devices includes a new requirement that design generative model 123 was not trained on.

At step 1002, design generative model 123 generates design 402 based on requirements 401 included in first requirement data 421 and stores design 402 in design data 124. First encoder 126 processes requirements 401 and generates a first requirement embedding. Decoder 128 processes the first requirement embedding and generates design 402. In some embodiments, decoder 128 includes a generative decoder configured to generate geometric models, component assemblies, parametric configurations, mesh structures, or other digital design representations corresponding to the requirement embedding. In some embodiments, design generative model 123 stores design 402 in design data 124.

At step 1003, second requirement bound value generator 420 generates, using design simulator 119, a second requirement bound value 405 based on second requirement 404 and design 402. In some examples, second requirement bound value generator 420 computes a requirement value N_{i,sim}(x) for design 402 x using design simulator 119, and then perturbs the requirement value with a random variance σ to generate a bound value as described in Equation 2. In some examples, second requirement bound value generator 420 synthetically generates a pair (Ñᵢ, x), where Ñᵢ serves as a constraint or requirement value associated with second requirement 404 nᵢ, and design 402 x is treated as a design that satisfies the bound in Equation 2.

At step 1004, second requirement data generator 116 stores second requirement bound value 405 and second requirement 404 in second requirement data 422.

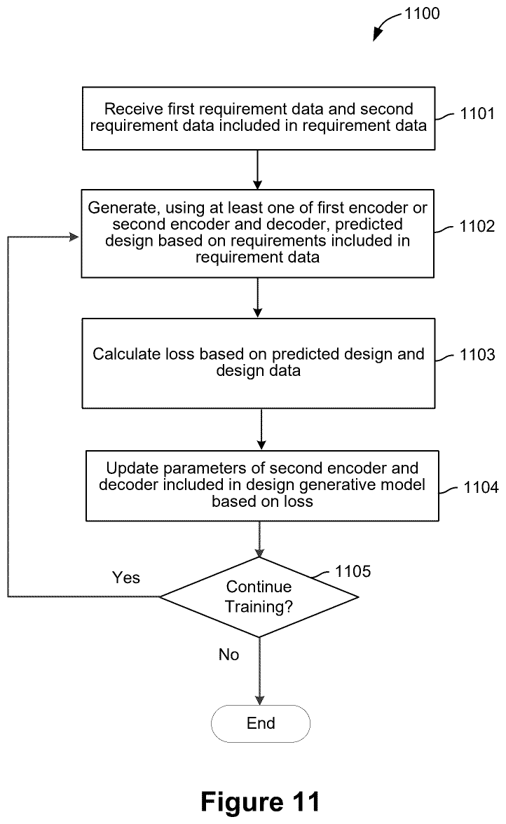

FIG. 11 is a flow diagram of method steps for training design generative model 123 based on first requirement data 421 and second requirement data 422, according to various embodiments. Although the method steps are described in conjunction with the systems of FIGS. 1-7, persons skilled in the art will understand that any system configured to perform the method steps in any order falls within the scope of the present embodiments.

As shown, a method 1100 begins with step 1101, where design generative model 123 receives first requirement data 421 and second requirement data 422.

At step 1102, design generative model 123 generates, using at least one of first encoder 126 or second encoder 127 and decoder 128, predicted design 410 based on requirements 401 included in requirement data 125. In some embodiments, first encoder 126 processes requirements 401 and generates a first requirement embedding. Second encoder 127 processes one or more second requirements included in second requirement data 422 and generates a second requirement embedding. Decoder 128 processes at least one of the first requirement embedding and the second requirement embedding and generates predicted design 410. In some embodiments, decoder 128 includes a generative decoder configured to generate geometric models, component assemblies, parametric configurations, mesh structures, or other digital design representations corresponding to at least one of the first requirement embedding or the second requirement embedding.

At step 1103, loss calculator 115 calculates loss 411 based on predicted design 410 and design data 124. In some embodiments, loss calculator 115 computes loss 411 by comparing predicted design 410 generated by design generative model 123 against a design included in design data 124. For example, loss 411 can include a log-probability loss and/or the like. In some embodiments, loss calculator 115 calculates the log-probability loss that encourages design generative model 123 to increase the likelihood of generating the design included in design data 124. In some examples, the log-probability loss can be calculated as given in Equation 1.

At step 1104, model trainer 114 updates parameters of second encoder 127 and decoder 128 based on loss 411. In some embodiments, model trainer 114 updates second encoder 127 and decoder 128 using gradient-based optimization techniques, such as SGD, Adam, RMSProp, and/or the like. In at least one embodiment, model trainer 114 keeps first encoder 126 fixed during training and updates only second encoder 127 and decoder 128.

At step 1105, model trainer 114 determines whether to continue training. In some embodiments, model trainer 114 iteratively updates second encoder 127 and decoder 128 over multiple training steps until meeting one or more convergence conditions, such as reaching a maximum number of training steps (e.g., 6 steps or 10 steps), loss 411 falling below a threshold value, loss 411 stabilizing across successive iterations, satisfying a simulator-defined performance criterion, and/or the like. When model trainer 114 determines to continue training, method 1100 returns to step 1102. When model trainer 114 determines not to continue training, method 1100 terminates.

FIG. 12 is a flow diagram of method steps for generating preferred designs 530 and rejected designs 521, according to various embodiments. Although the method steps are described in conjunction with the systems of FIGS. 1-7, persons skilled in the art will understand that any system configured to perform the method steps in any order falls within the scope of the present embodiments.

A method 1200 begins with step 1201, where design generative model 123 receives requirement data 125. In some embodiments, requirement data 125 includes one or more requirements 301 and corresponding requirement values that define the design objectives and constraints for design generation.

At step 1202, design generative model 123 generates designs 502 based on requirements 501 included in requirement data 125. In some embodiments, at least one of first encoder 126 or second encoder 127 processes requirements 501 and generates a requirement embedding. Decoder 128 processes the requirement embedding and generates designs 502. In some embodiments, decoder 128 includes a generative decoder configured to generate geometric models, component assemblies, parametric configurations, mesh structures, or other digital design representations corresponding to the requirement embedding. In some embodiments, design generative model 123 stores designs 502 in design data 124.

At step 1203, design simulator 119 simulates designs 502 to determine design performance values 503 based on requirements 501. In some embodiments, design simulator 119 performs one or more simulations, such as a physics-based simulation, a finite-element analysis, a computational fluid dynamics simulation, a thermal or energy-transfer simulation, an electrical circuit simulation, and/or the like, depending on each design 502. For example, for a given requirement 501 of interest rᵢ, design simulator 119 can compute a requirement performance value 503 N_{i, sim} (x) for each design 502 x.

At step 1204, preferred and rejected designs generator 117 generates preferred designs 522 and rejected designs 521 based on designs 502 and design performance values 503. In some embodiments, preferred and rejected designs generator 117 ranks designs 502 based on design performance values 503 returned by design simulator 119. In some examples, for three designs 502 x⁽¹⁾, x⁽²⁾, and x⁽³⁾ preferred and rejected designs generator 117 can order designs 502 based on the design performance values 503, such as N_{i,sim}(x⁽¹⁾)<N_{i,sim}(x⁽²⁾)<N_{i,sim}(x⁽³⁾), where designs 502 with lower performance values satisfy requirement 501 more effectively. In some embodiments, preferred and rejected designs generator 117 identifies at least one preferred design 520, such as the design achieving the lowest requirement performance value 503, and at least one rejected design 521, such as the design achieving a higher performance value 503. In some examples, preferred and rejected designs generator 117 determines a constraint bound value using μ=μ(N_{i,sim}(x^{(p)}), N_{i,sim}(x^{(r)}, where x^{(p)} denotes the preferred design 522 and x^{(r)} denotes the rejected design 521, and μ(⋅) includes a mean or averaging function. In some embodiments, preferred design 522 satisfies the constraint bound Nᵢ≤μ while rejected design 521 does not satisfy the constraint. In some embodiments, preferred and rejected designs generator 117 stores preferred designs 522 and rejected designs 521 in design data 124.

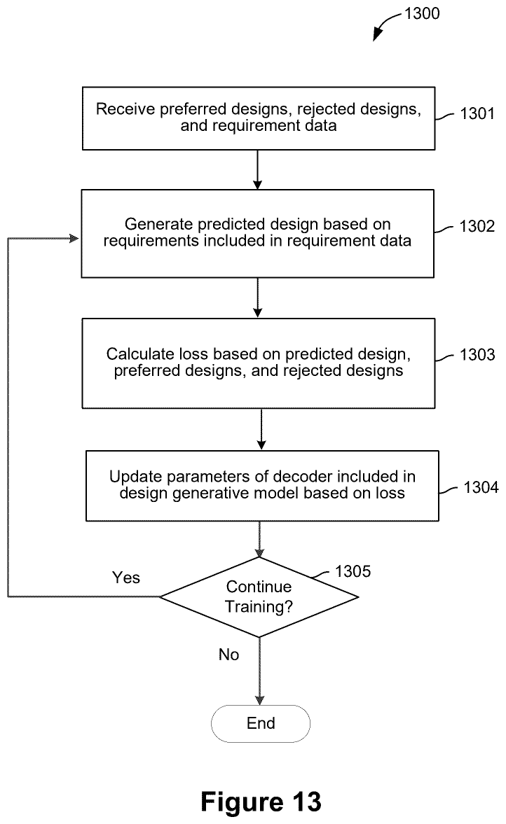

FIG. 13 is a flow diagram of method steps for training design generative model 123 based on preferred designs 522 and rejected designs 521, according to various embodiments. Although the method steps are described in conjunction with the systems of FIGS. 1-7, persons skilled in the art will understand that any system configured to perform the method steps in any order falls within the scope of the present embodiments.

As shown, a method 1300 begins with step 1301, where loss calculator 115 receives preferred designs 522 and rejected designs 521 and design generative model 123 receives requirement data 125.

At step 1302, design generative model 123 generates predicted design 510 based on requirements included in requirement data 125. In some embodiments, at least one of first encoder 126 or second encoder 127 processes the requirements and generates a requirement embedding. Decoder 128 processes the requirement embedding and generates predicted designs 510. In some embodiments, decoder 128 includes a generative decoder configured to generate geometric models, component assemblies, parametric configurations, mesh structures, or other digital design representations corresponding to the requirement embedding.

At step 1303, loss calculator 115 calculates loss 511 based on predicted design 510, preferred designs 522, and rejected designs 521. In some embodiments, loss calculator 115 computes loss 511 using a DPO loss that encourages design generative model 123 to increase the likelihood of generating preferred designs 522 relative to rejected designs 521 for a given requirement. For example, the DPO loss can be calculated as described in Equation 3. In some embodiments, loss calculator 115 computes loss 511 by evaluating the log-probabilities of preferred designs 522 and rejected designs 521 generated by design generative model 123 and weighting the log likelihoods according to Equation 3. In some examples, a previous checkpoint of design generative model 123 can be picked post hoc, subject to the criterion that a fixed percentage, such as 95 percent, of predicted designs 510 are valid.

At step 1304, model trainer 114 updates parameters of decoder 128 based on loss 511. In some embodiments, model trainer 114 updates decoder 128 using gradient-based optimization techniques, such as SGD, Adam, RMSProp, and/or the like. In at least one embodiment, model trainer 114 keeps first encoder 126 and second encoder 127 fixed during training and updates only decoder 128.

At step 1305, model trainer 114 determines whether to continue training. In some embodiments, model trainer 114 iteratively updates decoder 128 over multiple training steps until meeting one or more convergence conditions, such as reaching a maximum number of training steps (e.g., 20 steps), loss 511 falling below a threshold value, loss 511 stabilizing across successive iterations, satisfying a simulator-defined performance criterion, and/or the like. When model trainer 114 determines to continue training, method 1300 returns to step 1302. When model trainer 114 determines not to continue training, method 1300 terminates.

FIG. 14 is a flow diagram of method steps for training design generative model 123 based on design trajectory data 129, according to various embodiments. Although the method steps are described in conjunction with the systems of FIGS. 1-7, persons skilled in the art will understand that any system configured to perform the method steps in any order falls within the scope of the present embodiments.

As shown, a method 1400 begins with step 1401, where design generative model 123 receives requirement data 125. In some embodiments, requirement data 125 includes first requirement data 421 and second requirement data 422.

At step 1402, design generative model 123 generates designs 602 based on requirements 601 included in requirement data 125. In some embodiments, at least one of first encoder 126 or second encoder 127 processes requirements 601 and generates a requirement embedding. Decoder 128 processes the requirement embedding and generates designs 602. In some embodiments, decoder 128 includes a generative decoder configured to generate geometric models, component assemblies, parametric configurations, mesh structures, or other digital design representations corresponding to the requirement embedding.

At step 1403, design reward generator 620 generates, using design simulator 119, design rewards 603 based on designs 602 and requirements 601. In some embodiments, each requirement 601 rᵢ includes a target requirement bound value nᵢ. Design simulator 119 evaluates each design 602 x and computes an evaluated requirement value ñ(x), which indicates how well design 602 x satisfies requirement 601 rᵢ. In some embodiments, design reward generator 620 computes a reward value R(x, nᵢ) for each design 602 x using a simulator-based reward function normalized to the interval [−1,1]. For example, design reward generator 620 can compute design rewards 603 according to Equation 4. In Equation 4, a design 602 that satisfies the requirement (ñ(x)≤nᵢ) receives a reward of +1, while designs 602 that violate the requirement receive a reward approaching −1 as the magnitude of the violation increases. In some examples, design reward generator 620 computes design rewards 603 using a binary rule described as given in Equation 5 or another simulator-defined function that quantifies design performance relative to requirement 601.

At step 1404, design reward generator 620 stores design rewards 603 and designs 602 in design trajectory data 129.

At step 1405, design generative model 123 generates predicted designs 611 based on requirements 601 included in requirement data 125. In some embodiments, at least one of first encoder 126 or second encoder 127 processes requirements 601 and generates a requirement embedding. Decoder 128 processes the requirement embedding and generates predicted designs 611. In some embodiments, decoder 128 includes a generative decoder configured to generate geometric models, component assemblies, parametric configurations, mesh structures, or other digital design representations corresponding to the requirement embedding.

At step 1406, loss calculator 115 calculates loss 612 based on design trajectory data 129 and predicted designs 611. In some embodiments, loss calculator 115 calculates loss 612 based on design trajectories 610 included in design trajectory data 129 and predicted designs 611. In some embodiments, each design trajectory 610 includes a sequence of generated designs 602 and the corresponding design rewards 603. In some embodiments, loss calculator 115 calculates loss 612 using a PPO objective. The PPO loss encourages design generative model 123 to increase the probability of generating designs 602 that achieve higher simulator design rewards 603 while preventing overly large updates that could destabilize training. In some examples, loss calculator 115 calculates loss 612 according to Equation 6.

At step 1407, model trainer 114 updates parameters of decoder 128 based on loss 612. In some embodiments, model trainer 114 updates decoder 128 using gradient-based optimization techniques, such as SGD, Adam, RMSProp, and/or the like. In at least one embodiment, model trainer 114 keeps first encoder 126 and second encoder 127 fixed during training and updates only decoder 128.

At step 1408, model trainer 114 determines whether to continue training. In some embodiments, model trainer 114 iteratively updates decoder 128 over multiple training steps until meeting one or more convergence conditions, such as reaching a maximum number of training steps (e.g., 20 steps), loss 612 falling below a threshold value, loss 612 stabilizing across successive iterations, satisfying a simulator-defined performance criterion, and/or the like. When model trainer 114 determines to continue training, method 1400 returns to step 1402. When model trainer 114 determines not to continue training, method 1400 terminates.

FIG. 15 is a flow diagram of method steps for generating predicted design 702, according to various embodiments. Although the method steps are described in conjunction with the systems of FIGS. 1-7, persons skilled in the art will understand that any system configured to perform the method steps in any order falls within the scope of the present embodiments.

As shown, a method 1500 begins with step 1501, where trained design generative model 123 receives requirements 701. In some embodiments, requirements 701 are received from one or more I/O devices, such as user inputs, APIs, GUIs, automated design pipelines, and/or external software systems. In some examples, requirements 701 can include one or more requirement values that define design objectives, constraints, or operating conditions predicted design 702 must satisfy.

At step 1502, trained design generative model 123 generates predicted design 702 based on requirements 701. In some embodiments, at least one of trained first encoder 126 or trained second encoder 127 processes requirements 701 and generates a requirement embedding. Trained decoder 128 processes the requirement embedding and generates predicted design 702.

In sum, techniques are disclosed for training a design generative model using simulation. The design generative model is a machine learning model that is trained to process one or more first requirements and generate one or more first designs. The design generative model includes a first encoder, a second encoder, and a decoder. The first encoder and the second encoder are each another machine learning model that processes the first requirements and generates a requirement embedding. The decoder is yet another machine learning model that processes the requirement embedding and generates the first designs. In some embodiments, a model trainer trains the design generative model based on one or more requirement satisfying-designs generated by a design simulator. During the training, the design generative model uses the first encoder and the decoder to process the first requirements included in requirement data and generate the first designs. The design simulator simulates the first designs to determine the requirement satisfying-designs based on the first requirements. A loss calculator calculates a first loss based on the first designs and the requirement satisfying-designs. The model trainer uses the first loss to update one or more parameters of the decoder iteratively until one or more stopping criteria are met.

In some embodiments, a second requirement data generator uses the design simulator and the design generative model to process one or more second requirements and the first requirements included in first requirement data and generate second requirement data. During second requirement data generation, the design generative model uses the first encoder and the decoder to process the first requirements and generate one or more second designs. A second requirement bound value generator uses the design simulator to process the second designs and the second requirements and generate second requirement bound values, which are stored in the second requirement data along with the second requirements. The model trainer then trains the design generative model based on the first requirement data, the second requirement data, and design data. During the training, the first encoder processes the first requirement data and generates a first embedding. The second encoder processes the second requirement data and generates a second embedding. The decoder processes at least one of the first embedding and the second embedding to generate one or more first predicted designs. The loss calculator calculates a second loss based on the first predicted designs and the design data. The model trainer updates one or more parameters of the second encoder and the decoder based on the second loss until one or more stopping criteria are met.

In some embodiments, a preferred and rejected designs generator uses the design generative model and the design simulator to generate one or more preferred designs and one or more rejected designs based on the first requirement data and the second requirement data. During the design generation, the design generative model uses the decoder and at least one of the first encoder or the second encoder to process the first requirements and the second requirements and generate one or more third designs. The design simulator simulates the third designs and determines one or more design performance values based on the requirements. The preferred and rejected designs generator processes the third designs and the design performance values and generates the preferred designs and the rejected designs. The model trainer then trains the design generative model based on the first requirement data, the second requirement data, the preferred designs, and the rejected designs. During the training, at least one of the first encoder or the second encoder processes the first requirements and the second requirements and generates the requirement embedding. The decoder processes the requirement embedding and generates one or more second predicted designs. The loss calculator calculates a third loss based on the second predicted designs, the rejected designs, and the preferred designs. The model trainer updates parameters of the decoder based on the third loss iteratively until one or more stopping criteria are met.

In some embodiments, the model trainer trains the design generative model based on design trajectory data. A design trajectory generator uses the design generative model and the design simulator to process the first requirements and the second requirements and generate the design trajectory data. The design generative model uses at least one of the first encoder or the second encoder to process the first requirements and the second requirements and generate one or more fourth designs. A design reward generator uses the design simulator to simulate the fourth designs to generate one or more design rewards based on the first requirements and the second requirements. The design rewards along with the fourth designs are stored in the design trajectory data. During the training, the design generative model uses at least one of the first encoder or the second encoder and the decoder to process the first requirements and the second requirements and generate one or more third predicted designs. The loss calculator calculates a fourth loss based on the third predicted designs and one or more design trajectories included in the design trajectory data. The model trainer uses the fourth loss to update parameters of the decoder iteratively until one or more stopping criteria are met.

Once trained, the trained design generative model can be used by a design generation application to process one or more third requirements received from I/O devices and generate a fourth predicted design.

At least one technical advantage of the disclosed techniques relative to the prior art is that the disclosed techniques use simulation to provide accurate physics based supervisory signals that directly reflect real world performance and thereby overcome limitations associated with historical datasets that are static in nature. Rather than relying solely on curated CAD files, engineering drawings, or manually constructed examples, the disclosed techniques generate training data, preference feedback, or reward signals through a design simulator that evaluates each generated design under relevant physical, mechanical, thermal, aerodynamic, or electrical conditions. Another technical advantage of the disclosed techniques is that the disclosed techniques enable continuous refinement of a design generative model using simulation-derived bound values, preferences, or rewards without a requirement for human labels, expert review, or manual correction steps. Accordingly, the disclosed techniques improve technical performance, accuracy, and generalization capability of design generative models by aligning design generative models with simulator feedback during training.

These technical advantages provide one or more technological improvements over prior art approaches.

1. In some embodiments, a computer-implemented method for training a generative model to generate one or more designs includes: receiving first requirement data; performing, using a simulator and a first trained machine learning model, one or more operations to generate one or more requirement-satisfying designs based on the first requirement data, where the first trained machine learning model is trained to generate one or more first designs based on the first requirement data; performing, based on the one or more requirement-satisfying designs and the first requirement data, one or more training operations to retrain the first trained machine learning model to generate a second trained machine learning model; and generating, based on one or more first requirements and using the second trained machine learning model, one or more first predicted designs.

2. The computer-implemented method of clause 1, where performing the one or more operations to generate the one or more requirement-satisfying designs includes: generating, based on one or more second requirements included in the first requirement data, one or more first designs using the first trained machine learning model; and simulating, using the simulator, the one or more first designs to determine the one or more requirement-satisfying designs based on the one or more second requirements.

3. The computer-implemented method of any of clauses 1-2, where generating the one or more first designs includes: generating, based on one or more second requirements, a requirement embedding using an encoder included in the first trained machine learning model; and generating, based on the requirement embedding, the one or more first designs using a decoder included in the first trained machine learning model.

4. The computer-implemented method of any of clauses 1-3, where simulating the one or more first designs to determine the one or more requirement-satisfying designs includes generating, for each design included in the one or more first designs, a simulated requirement value vector that includes one or more simulated performance values associated with the one or more second requirements.

5. The computer-implemented method of any of clauses 1-4, where simulating the one or more first designs to determine the one or more requirement-satisfying designs includes verifying that a simulated performance value satisfies at least one of a target-value condition, a minimum-value condition, or a maximum-value condition.

6. The computer-implemented method of any of clauses 1-5, where simulating the one or more first designs to determine the one or more requirement-satisfying designs includes performing at least one of a physics-based simulation, a finite-element analysis, a computational fluid dynamics simulation, an energy-transfer simulation, or an electrical circuit simulation.

7. The computer-implemented method of any of clauses 1-6, where performing the one or more training operations to retrain the first trained machine learning model to generate the second trained machine learning model includes: generating, based on one or more second requirements included in the first requirement data, one or more second predicted designs using the first trained machine learning model; calculating, based on the one or more second predicted designs and the one or more requirement-satisfying designs, a loss; and updating, based on the loss, one or more parameters of a decoder included in the first trained machine learning model.

8. The computer-implemented method of any of clauses 1-7, where calculating the loss includes computing a log-probability loss that encourages the first trained machine learning model to increase a likelihood of generating the one or more requirement-satisfying designs.

9. The computer-implemented method of any of clauses 1-8, further including: receiving one or more second requirements; generating, based on the first requirement data, one or more second designs using the second trained machine learning model; and determining, based on the one or more second requirements and the one or more second designs, second requirement data using the simulator.

10. The computer-implemented method of any of clauses 1-9, where determining the second requirement data includes: computing a requirement value associated with a first design included in the one or more second designs using the simulator; perturbing the requirement value with a random variance to generate a bound value; and pairing the bound value and the first design to generate a second requirement bound value included in second requirement data.

11. The computer-implemented method of any of clauses 1-10, further including: generating, based on one or more first requirements included in the first requirement data, a first embedding using a first encoder included in the second trained machine learning model; generating, based on one or more third requirements included in the second requirement data, a second embedding using a second encoder included in the second trained machine learning model; generating, based on the first embedding and the second embedding, one or more second predicted designs using a decoder included in the second trained machine learning model; calculating, based on the one or more second predicted designs and the one or more second designs, a loss; and updating, based on the loss, one or more parameters of the second encoder and the decoder.

12. The computer-implemented method of any of clauses 1-11, where the loss includes a log-probability loss.

13. The computer-implemented method of any of clauses 1-12, where the decoder includes a generative decoder configured to generate at least one of one or more geometric models, one or more component assemblies, one or more parametric configurations, or one or more mesh structures.

14. In some embodiments, one or more non-transitory computer-readable media storing instructions that, when executed by one or more processors, cause the one or more processors to perform the steps of: receiving first requirement data; performing, using a simulator and a first trained machine learning model, one or more operations to generate one or more requirement-satisfying designs based on the first requirement data, where the first trained machine learning model is trained to generate one or more first designs based on the first requirement data; performing, based on the one or more requirement-satisfying designs and the first requirement data, one or more training operations to retrain the first trained machine learning model to generate a second trained machine learning model; and generating, based on one or more first requirements and using the second trained machine learning model, one or more first predicted designs.

15. The one or more non-transitory computer-readable media of clause 14, where performing the one or more operations to generate the one or more requirement-satisfying designs includes: generating, based on one or more second requirements included in the first requirement data, one or more first designs using the first trained machine learning model; and simulating, using the simulator, the one or more first designs to determine the one or more requirement-satisfying designs based on the one or more second requirements.

16. The one or more non-transitory computer-readable media of any of clauses 14-15, where generating the one or more first designs includes: generating, based on one or more second requirements, a requirement embedding using an encoder included in the first trained machine learning model; and generating, based on the requirement embedding, the one or more first designs using a decoder included in the first trained machine learning model.

17. The one or more non-transitory computer-readable media of any of clauses 14-16, where simulating the one or more first designs to determine the one or more requirement-satisfying designs includes verifying that a simulated performance value satisfies at least one of a target-value condition, a minimum-value condition, or a maximum-value condition.

18. The one or more non-transitory computer-readable media of any of clauses 14-17, where the instructions, when executed by the one or more processors, further cause the one or more processors to perform the steps of: receiving one or more second requirements; generating, based on the first requirement data, one or more second designs using the second trained machine learning model; and determining, based on the one or more second requirements and the one or more second designs, second requirement data using the simulator.

19. The one or more non-transitory computer-readable media of any of clauses 14-18, where determining the second requirement data includes: computing a requirement value associated with a first design included in the one or more second designs using the simulator; perturbing the requirement value with a random variance to generate a bound value; and pairing the bound value and the first design to generate a second requirement bound value included in second requirement data.

20. In some embodiments, a system, including: one or more memories storing instructions; and one or more processors that are coupled to the one or more memories and, when executing the instructions, are configured to: receive first requirement data; perform, using a simulator and a first trained machine learning model, one or more operations to generate one or more requirement-satisfying designs based on the first requirement data, where the first trained machine learning model is trained to generate one or more first designs based on the first requirement data; perform, based on the one or more requirement-satisfying designs and the first requirement data, one or more training operations to retrain the first trained machine learning model to generate a second trained machine learning model; and generate, based on one or more first requirements and using the second trained machine learning model, one or more first predicted designs.

21. In some embodiments, a computer-implemented method for training a generative model for to generate one or more designs includes: receiving requirement data; performing, using a simulator and a first trained machine learning model, one or more operations to generate one or more preferred designs and one or more rejected designs, where the first trained machine learning model is trained to generate one or more first designs based on the requirement data; performing, based on the requirement data, the one or more preferred designs, and the one or more rejected designs, one or more training operations to retrain the first trained machine learning model to generate a second trained machine learning model; and generating, based on one or more first requirements and using the second trained machine learning model, one or more first predicted designs.

22. The computer-implemented method of clause 21, where the one or more operations to generate the one or more preferred designs and the one or more rejected designs includes: generating, based on one or more second requirements included in the requirement data, one or more first designs using a decoder and at least one of a first encoder or a second encoder included in the first trained machine learning model; simulating the one or more first designs to determine one or more design performance values based on the one or more second requirements; and generating, based on the one or more first designs and the one or more design performance values, the one or more preferred designs and the one or more rejected designs.

23. The computer-implemented method of any of clauses 21-22, where generating the one or more preferred designs and the one or more rejected designs includes: ranking, based on the one or more design performance values, the one or more first designs; and selecting a first design included in the one or more first designs associated with a least performance value included in the one or more design performance values to generate a first preferred design included the one or more preferred designs.

24. The computer-implemented method of any of clauses 21-23, where generating the one or more preferred designs and the one or more rejected designs includes: ranking, based on the one or more design performance values, the one or more first designs; and selecting a first design included in the one or more first designs associated with a highest performance value included in the one or more design performance values to generate a first rejected design included the one or more rejected designs.

25. The computer-implemented method of any of clauses 21-24, further including determining, based on a first preferred design included in the one or more preferred designs and a first rejected design included in the one or more rejected designs, a constraint bound value using an averaging function.

26. The computer-implemented method of any of clauses 21-25, where: the first encoder is trained to generate a first requirement embedding based on first requirement data included in the requirement data; and the second encoder is trained to generate a second requirement embedding based on second requirement data included in the requirement data.

27. The computer-implemented method of any of clauses 21-26, where the decoder is trained to generate the one or more first designs based on a requirement embedding.

28. The computer-implemented method of any of clauses 21-27, where performing the one or more training operations to retrain the first trained machine learning model to generate the second trained machine learning model includes: generating, using the first trained machine learning model, one or more predicted designs based on the requirement data; calculating, based on the one or more predicted designs, the one or more preferred designs, and the one or more rejected designs, a loss; and updating, based on the loss, one or more parameters of a decoder included in the first trained machine learning model.

29. The computer-implemented method of any of clauses 21-28, where the loss includes a direct preference optimization loss that encourages the first trained machine learning model to increase a likelihood of generating the one or more preferred designs relative to the one or more rejected designs.

30. The computer-implemented method of any of clauses 21-29, where calculating the loss includes: evaluating one or more log-probabilities associated with the one or more preferred designs; and weighing the one or more log-probabilities.

31. The computer-implemented method of any of clauses 21-30, where calculating the loss includes determining a checkpoint of the first trained machine learning model such that a fixed percentage of one or more first designs generated by the first trained machine learning model are valid.

32. The computer-implemented method of any of clauses 21-31, where the requirement data includes at least one of one or more aerodynamic efficiency targets, one or more structural load limits, one or more thermal dissipation thresholds, one or more manufacturing cost budgets, one or more material weight limits, or one or more regulatory compliance conditions.

33. In some embodiments, one or more non-transitory computer-readable media storing instructions that, when executed by one or more processors, cause the one or more processors to perform the steps of: receiving requirement data; performing, using a simulator and a first trained machine learning model, one or more operations to generate one or more preferred designs and one or more rejected designs, where the first trained machine learning model is trained to generate one or more first designs based on the requirement data; performing, based on the requirement data, the one or more preferred designs, and the one or more rejected designs, one or more training operations to retrain the first trained machine learning model to generate a second trained machine learning model; and generating, based on one or more first requirements and using the second trained machine learning model, one or more first predicted designs.

34. The one or more non-transitory computer-readable media of clause 33, where the one or more operations to generate the one or more preferred designs and the one or more rejected designs includes: generating, based on one or more second requirements included in the requirement data, one or more first designs using a decoder and at least one of a first encoder or a second encoder included in the first trained machine learning model; simulating the one or more first designs to determine one or more design performance values based on the one or more second requirements; and generating, based on the one or more first designs and the one or more design performance values, the one or more preferred designs and the one or more rejected designs.

35. The one or more non-transitory computer-readable media of any of clauses 33-34, where generating the one or more preferred designs and the one or more rejected designs includes: ranking, based on the one or more design performance values, the one or more first designs; and selecting a first design included in the one or more first designs associated with a least performance value included in the one or more design performance values to generate a first preferred design included the one or more preferred designs.

36. The one or more non-transitory computer-readable media of any of clauses 33-35, where generating the one or more preferred designs and the one or more rejected designs includes: ranking, based on the one or more design performance values, the one or more first designs; and selecting a first design included in the one or more first designs associated with a highest performance value included in the one or more design performance values to generate a first rejected design included the one or more rejected designs.

37. The one or more non-transitory computer-readable media of any of clauses 33-36, where performing the one or more training operations to retrain the first trained machine learning model to generate the second trained machine learning model includes: generating, using the first trained machine learning model, one or more predicted designs based on the requirement data; calculating, based on the one or more predicted designs, the one or more preferred designs, and the one or more rejected designs, a loss; and updating, based on the loss, one or more parameters of a decoder included in the first trained machine learning model.

38. The one or more non-transitory computer-readable media of any of clauses 33-37, where the loss includes a direct preference optimization loss that encourages the first trained machine learning model to increase a likelihood of generating the one or more preferred designs relative to the one or more rejected designs.

39. The one or more non-transitory computer-readable media of any of clauses 33-38, where calculating the loss includes determining a checkpoint of the first trained machine learning model such that a fixed percentage of one or more first designs generated by the first trained machine learning model are valid.

40. In some embodiments, a system, including: one or more memories storing instructions; and one or more processors that are coupled to the one or more memories and, when executing the instructions, are configured to: receive requirement data; perform, using a simulator and a first trained machine learning model, one or more operations to generate one or more preferred designs and one or more rejected designs, where the first trained machine learning model is trained to generate one or more first designs based on the requirement data; perform, based on the requirement data, the one or more preferred designs, and the one or more rejected designs, one or more training operations to retrain the first trained machine learning model to generate a second trained machine learning model; and generate, based on one or more first requirements and using the second trained machine learning model, one or more first predicted designs.

41. In some embodiments, a computer-implemented method for training a generative model to generate one or more designs includes: receiving requirement data; performing, based on the requirement data, one or more operations to generate one or more design trajectories using a first trained machine learning model, where the first trained machine learning model is trained to generate one or more first designs; performing, based on the requirement data and the one or more design trajectories, one or more training operations to retrain the first trained machine learning model to generate a second trained machine learning model; and generating, based on one or more first requirements and using the second trained machine learning model, one or more first predicted designs.

42. The computer-implemented method of clause 41, where performing the one or more operations to generate the one or more design trajectories includes: generating, based on one or more second requirements included in the requirement data, one or more first designs using a decoder and at least one of a first encoder or a second encoder included in the first trained machine learning model; simulating the one or more first designs to determine one or more design rewards based on the one or more second requirements; and generating, based on the one or more first designs and the one or more design rewards, the one or more design trajectories.

43. The computer-implemented method of any of clauses 41-42, where: the first encoder is trained to generate a first requirement embedding based on first requirement data included in the requirement data; and the second encoder is trained to generate a second requirement embedding based on second requirement data included in the requirement data.

44. The computer-implemented method of any of clauses 41-43, where the decoder is trained to generate the one or more first designs based on a requirement embedding.

45. The computer-implemented method of any of clauses 41-44, where simulating the one or more first designs to determine the one or more design rewards includes evaluating a second design included in the one or more first designs to compute an evaluated requirement value.

46. The computer-implemented method of any of clauses 41-45, where simulating the one or more first designs to determine the one or more design rewards includes computing, based on a target requirement bound associated with a first requirement included in one or more second requirement values and an evaluated requirement value, a reward value included in the one or more design rewards using a reward function that is normalized.

47. The computer-implemented method of any of clauses 41-46, where simulating the one or more first designs to determine the one or more design rewards includes: assigning a first positive reward to a second design associated with an evaluated requirement value that is below a target requirement value; and assigning a negative of the first positive reward to a second design associated with an evaluated requirement value that is above the target requirement value.

48. The computer-implemented method of any of clauses 41-47, where simulating the one or more first designs to determine the one or more design rewards includes using a binary rule.

49. The computer-implemented method of any of clauses 41-48, where performing the one or more training operations to retrain the first trained machine learning model to generate the second trained machine learning model includes: generating, using the first trained machine learning model, one or more predicted designs based on the requirement data; calculating, based on the one or more predicted designs and the one or more design trajectories, a loss; and updating, based on the loss, one or more parameters of a decoder included in the first trained machine learning model.

50. The computer-implemented method of any of clauses 41-49, where the loss includes a proximal-policy-optimization objective.

51. The computer-implemented method of any of clauses 41-50, where calculating the loss includes calculating a Kullback-Leibler divergence penalty based on the first trained machine learning model and a previous checkpoint of the first trained machine learning model.

52. The computer-implemented method of any of clauses 41-51, where performing the one or more training operations to retrain the first trained machine learning model to generate a second trained machine learning model includes storing a checkpoint of the first trained machine learning model.

53. The computer-implemented method of any of clauses 41-52, where the one or more first designs includes at least one of one or more geometric computer-aided-design meshes, one or more parametric component configurations, one or more mechanical assemblies, one or more electrical layouts, one or more structural topologies, or one or more three-dimensional surface representations.

54. In some embodiments, one or more non-transitory computer-readable media storing instructions that, when executed by one or more processors, cause the one or more processors to perform the steps of: receiving requirement data; performing, based on the requirement data, one or more operations to generate one or more design trajectories using a first trained machine learning model, where the first trained machine learning model is trained to generate one or more first designs; performing, based on the requirement data and the one or more design trajectories, one or more training operations to retrain the first trained machine learning model to generate a second trained machine learning model; and generating, based on one or more first requirements and using the second trained machine learning model, one or more first predicted designs.

55. The one or more non-transitory computer-readable media of clause 54, where performing the one or more operations to generate the one or more design trajectories includes: generating, based on one or more second requirements included in the requirement data, one or more first designs using a decoder and at least one of a first encoder or a second encoder included in the first trained machine learning model; simulating the one or more first designs to determine one or more design rewards based on the one or more second requirements; and generating, based on the one or more first designs and the one or more design rewards, the one or more design trajectories.

56. The one or more non-transitory computer-readable media of any of clauses 54-55, where simulating the one or more first designs to determine the one or more design rewards includes computing, based on a target requirement bound associated with a first requirement included in one or more second requirement values and an evaluated requirement value, a reward value included in the one or more design rewards using a reward function that is normalized.

57. The one or more non-transitory computer-readable media of any of clauses 54-56, where simulating the one or more first designs to determine the one or more design rewards includes: assigning a first positive reward to a second design associated with an evaluated requirement value that is below a target requirement value; and assigning a negative of the first positive reward to a second design associated with an evaluated requirement value that is above the target requirement value.

58. The one or more non-transitory computer-readable media of any of clauses 54-57, where performing the one or more training operations to retrain the first trained machine learning model to generate the second trained machine learning model includes: generating, using the first trained machine learning model, one or more predicted designs based on the requirement data; calculating, based on the one or more predicted designs and the one or more design trajectories, a loss; and updating, based on the loss, one or more parameters of a decoder included in the first trained machine learning model.

59. The one or more non-transitory computer-readable media of any of clauses 54-58, where the loss includes a proximal-policy-optimization objective.

60. In some embodiments, a system, including one or more memories storing instructions; and one or more processors that are coupled to the one or more memories and, when executing the instructions, are configured to receive requirement data; perform, based on the requirement data, one or more operations to generate one or more design trajectories using a first trained machine learning model, where the first trained machine learning model is trained to generate one or more first designs; perform, based on the requirement data and the one or more design trajectories, one or more training operations to retrain the first trained machine learning model to generate a second trained machine learning model; and generate, based on one or more first requirements and using the second trained machine learning model, one or more first predicted designs.

Any and all combinations of any of the claim elements recited in any of the claims and/or any elements described in this application, in any fashion, fall within the contemplated scope of the present disclosure and protection.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments.

Aspects of the present embodiments may be embodied as a system, method or computer program product. Accordingly, aspects of the present disclosure may take the form of an entirely hardware embodiment, an entirely software embodiment (including firmware, resident software, micro-code, etc.) or an embodiment combining software and hardware aspects that may all generally be referred to herein as a “module” or “system.” Furthermore, aspects of the present disclosure may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

Aspects of the present disclosure are described above with reference to flowchart illustrations and/or block diagrams of methods, apparatus (systems) and computer program products according to embodiments of the disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine. The instructions, when executed via the processor of the computer or other programmable data processing apparatus, enable the implementation of the functions/acts specified in the flowchart and/or block diagram block or blocks. Such processors may be, without limitation, general purpose processors, special-purpose processors, application-specific processors, or field-programmable gate arrays.

The flowchart and block diagrams in the figures illustrate the architecture, functionality, and operation of possible implementations of systems, methods and computer program products according to various embodiments of the present disclosure. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

While the preceding is directed to embodiments of the present disclosure, other and further embodiments of the disclosure may be devised without departing from the basic scope thereof, and the scope thereof is determined by the claims that follow.

What is claimed is:

1. A computer-implemented method for training a generative model to generate one or more designs, the method comprising:
receiving first requirement data;
performing, using a simulator and a first trained machine learning model, one or more operations to generate one or more requirement-satisfying designs based on the first requirement data, wherein the first trained machine learning model is trained to generate one or more first designs based on the first requirement data;
performing, based on the one or more requirement-satisfying designs and the first requirement data, one or more training operations to retrain the first trained machine learning model to generate a second trained machine learning model; and
generating, based on one or more first requirements and using the second trained machine learning model, one or more first predicted designs.

2. The computer-implemented method of claim 1, wherein performing the one or more operations to generate the one or more requirement-satisfying designs comprises:
generating, based on one or more second requirements included in the first requirement data, one or more first designs using the first trained machine learning model; and
simulating, using the simulator, the one or more first designs to determine the one or more requirement-satisfying designs based on the one or more second requirements.

3. The computer-implemented method of claim 2, wherein generating the one or more first designs comprises:
generating, based on one or more second requirements, a requirement embedding using an encoder included in the first trained machine learning model; and
generating, based on the requirement embedding, the one or more first designs using a decoder included in the first trained machine learning model.

4. The computer-implemented method of claim 2, wherein simulating the one or more first designs to determine the one or more requirement-satisfying designs comprises generating, for each design included in the one or more first designs, a simulated requirement value vector that includes one or more simulated performance values associated with the one or more second requirements.

5. The computer-implemented method of claim 2, wherein simulating the one or more first designs to determine the one or more requirement-satisfying designs comprises verifying that a simulated performance value satisfies at least one of a target-value condition, a minimum-value condition, or a maximum-value condition.

6. The computer-implemented method of claim 2, wherein simulating the one or more first designs to determine the one or more requirement-satisfying designs comprises performing at least one of a physics-based simulation, a finite-element analysis, a computational fluid dynamics simulation, an energy-transfer simulation, or an electrical circuit simulation.

7. The computer-implemented method of claim 1, wherein performing the one or more training operations to retrain the first trained machine learning model to generate the second trained machine learning model comprises:
generating, based on one or more second requirements included in the first requirement data, one or more second predicted designs using the first trained machine learning model;
calculating, based on the one or more second predicted designs and the one or more requirement-satisfying designs, a loss; and
updating, based on the loss, one or more parameters of a decoder included in the first trained machine learning model.

8. The computer-implemented method of claim 7, wherein calculating the loss comprises computing a log-probability loss that encourages the first trained machine learning model to increase a likelihood of generating the one or more requirement-satisfying designs.

9. The computer-implemented method of claim 1, further comprising:
receiving one or more second requirements;
generating, based on the first requirement data, one or more second designs using the second trained machine learning model; and
determining, based on the one or more second requirements and the one or more second designs, second requirement data using the simulator.

10. The computer-implemented method of claim 9, wherein determining the second requirement data comprises:
computing a requirement value associated with a first design included in the one or more second designs using the simulator;
perturbing the requirement value with a random variance to generate a bound value; and
pairing the bound value and the first design to generate a second requirement bound value included in second requirement data.

11. The computer-implemented method of claim 9, further comprising:
generating, based on one or more first requirements included in the first requirement data, a first embedding using a first encoder included in the second trained machine learning model;
generating, based on one or more third requirements included in the second requirement data, a second embedding using a second encoder included in the second trained machine learning model;
generating, based on the first embedding and the second embedding, one or more second predicted designs using a decoder included in the second trained machine learning model;
calculating, based on the one or more second predicted designs and the one or more second designs, a loss; and
updating, based on the loss, one or more parameters of the second encoder and the decoder.

12. The computer-implemented method of claim 11, wherein the loss comprises a log-probability loss.

13. The computer-implemented method of claim 11, wherein the decoder comprises a generative decoder configured to generate at least one of one or more geometric models, one or more component assemblies, one or more parametric configurations, or one or more mesh structures.

14. One or more non-transitory computer-readable media storing instructions that, when executed by one or more processors, cause the one or more processors to perform the steps of:
receiving first requirement data;
performing, using a simulator and a first trained machine learning model, one or more operations to generate one or more requirement-satisfying designs based on the first requirement data, wherein the first trained machine learning model is trained to generate one or more first designs based on the first requirement data;
performing, based on the one or more requirement-satisfying designs and the first requirement data, one or more training operations to retrain the first trained machine learning model to generate a second trained machine learning model; and
generating, based on one or more first requirements and using the second trained machine learning model, one or more first predicted designs.

15. The one or more non-transitory computer-readable media of claim 14, wherein performing the one or more operations to generate the one or more requirement-satisfying designs comprises:
generating, based on one or more second requirements included in the first requirement data, one or more first designs using the first trained machine learning model; and
simulating, using the simulator, the one or more first designs to determine the one or more requirement-satisfying designs based on the one or more second requirements.

16. The one or more non-transitory computer-readable media of claim 15, wherein generating the one or more first designs comprises:
generating, based on one or more second requirements, a requirement embedding using an encoder included in the first trained machine learning model; and
generating, based on the requirement embedding, the one or more first designs using a decoder included in the first trained machine learning model.

17. The one or more non-transitory computer-readable media of claim 15, wherein simulating the one or more first designs to determine the one or more requirement-satisfying designs comprises verifying that a simulated performance value satisfies at least one of a target-value condition, a minimum-value condition, or a maximum-value condition.

18. The one or more non-transitory computer-readable media of claim 14, wherein the instructions, when executed by the one or more processors, further cause the one or more processors to perform the steps of:
receiving one or more second requirements;
generating, based on the first requirement data, one or more second designs using the second trained machine learning model; and
determining, based on the one or more second requirements and the one or more second designs, second requirement data using the simulator.

19. The one or more non-transitory computer-readable media of claim 18, wherein determining the second requirement data comprises:
computing a requirement value associated with a first design included in the one or more second designs using the simulator;
perturbing the requirement value with a random variance to generate a bound value; and
pairing the bound value and the first design to generate a second requirement bound value included in second requirement data.

20. A system, comprising:
one or more memories storing instructions; and
one or more processors that are coupled to the one or more memories and, when executing the instructions, are configured to:
receive first requirement data;
perform, using a simulator and a first trained machine learning model, one or more operations to generate one or more requirement-satisfying designs based on the first requirement data, wherein the first trained machine learning model is trained to generate one or more first designs based on the first requirement data;
perform, based on the one or more requirement-satisfying designs and the first requirement data, one or more training operations to retrain the first trained machine learning model to generate a second trained machine learning model; and
generate, based on one or more first requirements and using the second trained machine learning model, one or more first predicted designs.
